(19) United States
(12) Patent Application Publication
(10) Pub. No.: US 2023/0420628 A1
(43) Pub. Date: Dec. 28, 2023

(54) DISPLAY DEVICE AND METHOD OF MANUFACTURING THE SAME

(71) Applicant: Samsung Display Co., LTD., Yongin-si (KR)

(72) Inventors: No Kyung PARK, Yongin-si (KR); Kyung Bae KIM, Yongin-si (KR); Sun Kwun SON, Yongin-si (KR); Dong Hee SHIN, Yongin-si (KR)

(21) Appl. No.: 18/212,652

(22) Filed: Jun. 21, 2023

(30) Foreign Application Priority Data
Jun. 24, 2022 (KR) 10-2022-0077715

(51) Int. Cl. H01L 33/62; H01L 25/16; H01L 33/48

(52) U.S. Cl. CPC H01L 33/62; H01L 25/167; H01L 33/483; H01L 2933/0066

(57) ABSTRACT

A display device includes: first to fourth alignment electrodes sequentially arranged while being spaced from each other in a first direction in a first emission area; a bank on the first to fourth alignment electrodes, the bank including first and second horizontal extension parts extending in the first direction and first to third vertical extension parts extending in a second direction crossing the first direction, the bank partitioning the first emission area and a second emission area; first light emitting elements overlapping with the first alignment electrode and the second alignment electrode on the first alignment electrode and the second alignment electrode; second light emitting elements overlapping with the second alignment electrode and the third alignment electrode on the second alignment electrode and the third alignment electrode; and third light emitting elements overlapping with the third and fourth alignment electrodes on the third and fourth alignment electrodes.

### CROSS-REFERENCE TO RELATED APPLICATION

The present application claims priority to and the benefit of Korean patent application No. 10-2022-0077715 filed on Jun. 24, 2022, in the Korean Intellectual Property Office, the entire disclosure of which is incorporated by reference herein.

### BACKGROUND

### 1. Field

The present disclosure generally relates to a display device and a method of manufacturing the same.

### 2. Related Art

Recently, as interest in information displays is increased, research and development of display devices have been continuously conducted.

### SUMMARY

One or more embodiments of the present disclosure provide a display device including a vertical extending part of a bank and an alignment electrode overlapping with emission areas at both sides of the vertical extending part.

One or more embodiments of the present disclosure also provide a method of manufacturing a display device, in which light emitting elements are arranged by applying one alignment signal to an alignment electrode overlapping with a vertical extending part of a bank.

In accordance with one or more embodiments of the present disclosure, there is provided a display device including: first, second, third, and fourth alignment electrodes sequentially arranged while being spaced from each other in a first direction in a first emission area; a bank on the first, second, third, and fourth alignment electrodes, the bank including first and second horizontal extension parts extending in the first direction and first, second, and third vertical extension parts extending in a second direction crossing the first direction, the bank partitioning the first emission area and a second emission area; first light emitting elements overlapping with the first alignment electrode and the second alignment electrode; second light emitting elements overlapping with the second alignment electrode and the third alignment electrode; and third light emitting elements overlapping with the third alignment electrode and the fourth alignment electrode, wherein the first alignment electrode overlaps with the first vertical extension part and the first emission area, and wherein the fourth alignment electrode overlaps with the first emission area, the second emission area, and the second vertical extension part.

When the first, second, and third light emitting elements are aligned, the first alignment electrode and the third alignment electrode are configured to receive a first alignment signal, and the second alignment electrode and the fourth alignment electrode is configured to receive a second alignment signal.

The first alignment signal may be different from the second alignment signal. A planar shape of the first alignment electrode may be identical to a planar shape of the fourth alignment electrode.

Each of the first alignment electrode and the fourth alignment electrode may include a first branch electrode and a second branch electrode extending in the second direction and overlapping with the bank.

The first branch electrode and the second branch electrode may respectively overlap with emission areas adjacent to each other.

The display device may further include a first pixel electrode, a first connection electrode, a second connection electrode, and a second pixel electrode, in each of the first emission area and the second emission area, that are spaced from each other along the first direction.

The first light emitting elements may be connected in parallel between the first pixel electrode and the first connection electrode, the second light emitting elements may be connected in parallel between the first connection electrode and the second connection electrode, and the third light emitting elements may be connected in parallel between the second connection electrode and the second pixel electrode.

The first light emitting elements, the second light emitting elements, and the third light emitting elements may be connected in series.

The first pixel electrode may overlap with a portion of the first alignment electrode, the first connection electrode may overlap with a portion of the second alignment electrode, the second connection electrode may overlap with a portion of the third alignment electrode, and the second pixel electrode may overlap with a portion of the fourth alignment electrode.

The first pixel electrode may be electrically connected to a transistor thereunder through a first contact hole at a portion not overlapping with the first alignment electrode.

The second pixel electrode may be electrically connected to a power line thereunder through a second contact hole at a portion not overlapping with the fourth alignment electrode.

The first pixel electrode may be insulated from the first alignment electrode, and the second pixel electrode may be insulated from the fourth alignment electrode.

The display device may further include fifth, sixth, and seventh alignment electrodes sequentially arranged while being spaced from each other along the first direction in the second emission area. The seventh alignment electrode may overlap with the second emission area and the third vertical extension part.

When the first, second, and third light emitting elements are aligned, the sixth alignment electrode is configured to receive the second alignment signal, and the fifth alignment electrode and the seventh alignment electrode are configured to receive the first alignment signal.

The fourth alignment electrode may include: a first sub-electrode overlapping with the third light emitting elements and the second vertical extension part; and a second sub-electrode spaced from the first sub-electrode, the second sub-electrode overlapping with the second vertical extension part and the second emission area.

The first pixel electrode may be electrically connected to the first alignment electrode through a first contact hole, and the second pixel electrode may be electrically connected to the first sub-electrode through a second contact hole.

In accordance with one or more embodiments of the present disclosure, there is provided a method of manufacturing a display device, the method including: forming, on a substrate, first, second, third, and fourth alignment electrodes arranged while being spaced from each other along a first direction; forming a bank defining a first emission area and a second emission area on the first, second, third, and fourth alignment electrodes; providing light emitting elements in the first emission area and the second emission area; and arranging the light emitting elements by applying a first alignment signal to the first alignment electrode and the third alignment electrode and applying a second alignment signal to the second alignment electrode and the fourth alignment electrode, wherein the bank includes first and second horizontal extension parts extending in the first direction and first, second, and third vertical extension parts extending in a second direction crossing the first direction, and wherein the first alignment electrode overlaps with the first vertical extension part and the first emission area, and the fourth alignment electrode overlaps with the first emission area, the second emission area, and the second vertical extension part.

The first alignment signal may be different from the second alignment signal, and wherein a planar shape of the first alignment electrode may be identical to a planar shape of the fourth alignment electrode.

The light emitting elements may be arranged in three columns in each of the first emission area and the second emission area.

The method may further include cutting both ends of each of the second alignment electrode and the third alignment electrode.

In the display device and the method of manufacturing the same in accordance with the present disclosure, alignment electrodes (e.g., the first, fourth, and seventh alignment electrodes) are disposed such that only one of the first alignment signal and the second alignment signal is transferred to each of alignment electrodes overlapping with each of the vertical extension parts. Thus, formation of an electric field on the bottom of the bank in an alignment process of light emitting elements can be suppressed. Accordingly, in arrangement of the light emitting elements forming first to third serial stages, an arrangement defect in which light emitting elements are disposed on the bank (e.g., the vertical extension parts) while being separated from positions thereof can be reduced or minimized.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a perspective cutaway view schematically illustrating a light emitting element in accordance with one or more embodiments of the present disclosure.

FIG. 2 is a sectional view illustrating an example of the light emitting element shown in FIG. 1.

FIG. 3 is a schematic plan view illustrating a display device in accordance with one or more embodiments of the present disclosure.

FIG. 4 is a circuit diagram illustrating an example of a pixel included in the display device shown in FIG. 3.

FIG. 5 is a circuit diagram illustrating an example of the pixel included in the display device shown in FIG. 3.

FIGS. 6 to 8 are schematic plan views illustrating an example of pixels included in the display device shown in FIG. 3.

FIG. 9 is a schematic sectional view illustrating an example taken along the line I-I′ shown in FIGS. 7 and 8.

FIGS. 10A to 10C are schematic sectional views illustrating examples of a partial area shown in FIG. 8.

FIG. 11 is a conceptual view illustrating an example of alignment electrodes included in the pixels shown in FIG. 7.

FIG. 12 is a schematic plan view illustrating an example of the pixels included in the display device shown in FIG. 3.

FIG. 13 is a conceptual view illustrating an example of alignment electrodes included in the pixels shown in FIG. 12.

FIGS. 14 and 15 are schematic plan views illustrating an example of the pixels included in the display device shown in FIG. 3.

FIG. 16 is a schematic sectional view illustrating an example of a partial area shown in FIG. 15.

FIGS. 17 to 20 are schematic plan views illustrating a method of manufacturing the display device in accordance with embodiments of the present disclosure.

### DETAILED DESCRIPTION

Hereinafter, embodiments of the present disclosure will be described in more detail with reference to the accompanying drawings. Throughout the drawings, the same reference numerals are given to the same elements, and their overlapping descriptions will be omitted.

One or more embodiments of the present disclosure are provided only for illustrative purposes and for full understanding of the scope of the present disclosure by those skilled in the art. However, the present disclosure is not limited to the embodiments, and it should be understood that the present disclosure includes modification examples or change examples without departing from the spirit and scope of the present disclosure.

The drawings attached to the present specification are provided to easily explain the present disclosure, and the shapes shown in the drawings may be exaggerated and displayed as necessary to help understanding of the present disclosure, and thus the present disclosure is not limited to the drawings.

In the present specification, when it is determined that a detailed description of a known configuration or function related to the present disclosure may obscure the gist of the present disclosure, a detailed description thereof will be omitted as necessary.

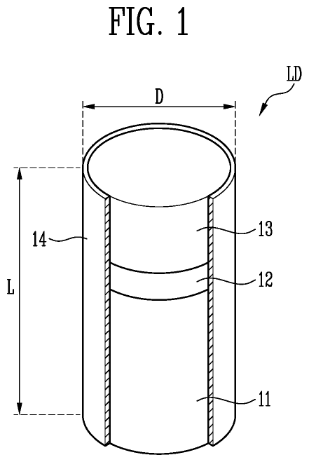

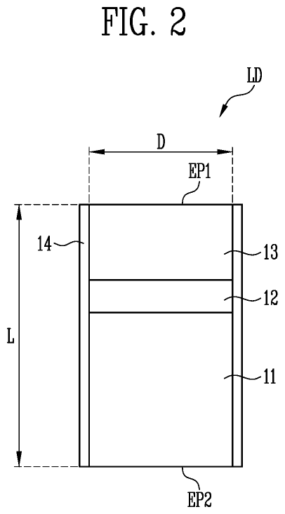

FIG. 1 is a perspective cutaway view schematically illustrating a light emitting element in accordance with embodiments of the present disclosure. FIG. 2 is a sectional view illustrating an example of the light emitting element shown in FIG. 1.

Referring to FIGS. 1 and 2, the light emitting element LD may include a first semiconductor layer 11, a second semiconductor layer 13, and an active layer 12 interposed between the first and second semiconductor layers 11 and 13. In an example, the light emitting element LD may be implemented with a light emitting stack structure (or stack pattern) in which the first semiconductor layer 11, the active layer 12, and the second semiconductor layer 13 are sequentially stacked.

The light emitting element LD may be provided in a shape extending in one direction. When assuming that an extending direction of the light emitting element LD is a length direction, the light emitting element LD may include a first end portion EP1 and a second end portion EP2 along the length direction. One semiconductor layer selected from the first semiconductor layer 11 and the second semiconductor layer 13 may be located at the first end portion EP1 of the light emitting element LD, and the other semiconductor layer selected from the first semiconductor layer 11 and the second semiconductor layer 13 may be located at the second end portion EP2 of the light emitting element LD.

The light emitting element LD may be provided in various shapes. In an example, the light emitting element LD may have a rod-like shape, a bar-like shape, a pillar-like shape, or the like, which is long in its length direction (i.e., its aspect ratio is greater than 1) as shown in FIG. 1. In another example, the light emitting element LD may have a rod-like shape, a bar-like shape, a pillar-like shape, or the like, which is short in its length direction (i.e., its aspect ratio is smaller than 1). In still another example, the light emitting element LD may have a rod-like shape, a bar-like shape, a pillar-like shape, or the like, of which aspect ratio is 1.

The light emitting element LD may include, for example, a light emitting diode (LED) manufactured small enough to have a diameter D and/or a length L to a degree of a nano scale (or nanometers) to a micro scale (micrometers).

When the light emitting element LD is long in its length direction (i.e., its aspect ratio is greater than 1), the diameter D of the light emitting element LD may be about 0.5 μm to about 6 μm, and the length L of the light emitting element LD may be about 1 μm to about 10 μm. However, the diameter D and the length L of the light emitting element LD are not limited thereto, and the size of the light emitting element LD may be changed to accord with requirement conditions (or design conditions) of a lighting device or a self-luminous display device, to which the light emitting element LD is applied.

The first semiconductor layer 11 may include, for example, at least one n-type semiconductor layer. The first semiconductor layer 11 may include an upper surface in contact with the active layer 12 and a lower surface exposed to the outside along the length direction of the light emitting element LD. The lower surface of the first semiconductor layer 11 may be one end portion (or bottom end portion) of the light emitting element LD.

The active layer 12 is formed on the first semiconductor layer 11, and may be formed in a single or multiple quantum well structure. In an example, when the active layer 12 is formed in the multiple quantum well structure, a barrier layer, a strain reinforcing layer, and a well layer, which constitute one unit, may be periodically and repeatedly stacked in the active layer 12. The strain reinforcing layer may have a lattice constant smaller than that of the barrier layer, to further reinforce strain, e.g., compressive strain applied to the well layer. However, the structure of the active layer 12 is not limited to the above-described embodiment.

The active layer 12 may emit light having a wavelength of 400 nm to 900 nm, and use a double hetero structure. The active layer 12 may include a first surface in contact with the first semiconductor layer 11 and a second surface in contact with the second semiconductor layer 13.

In one or more embodiments, a color (or light output color) of the light emitting element LD may be determined according to a wavelength of light emitted from the active layer 12. The color of the light emitting element LD may determine a color of a pixel corresponding thereto. For example, the light emitting element LD may emit red light, green light, or blue light.

When an electric field having a suitable voltage (e.g., a predetermined voltage) or more is applied between both the end portions of the light emitting element LD, the light emitting element LD emits light as electron-hole pairs are combined in the active layer 12. The light emission of the light emitting element LD is controlled by using such a principle, so that the light emitting element LD can be used as a light source (or light emitting source) for various light emitting devices, including a pixel of a display device.

The second semiconductor layer 13 is formed on the second surface of the active layer 12, and may include a semiconductor layer having a type different from that of the first semiconductor layer 11.

The second semiconductor layer 13 may include a lower surface in contact with the second surface and an upper surface exposed to the outside along the length direction of the light emitting element LD. The upper surface of the second semiconductor layer 13 may be the other end portion (or top end portion) of the light emitting element LD.

In one or more embodiments, the first semiconductor layer 11 and the second semiconductor layer 13 may have different thicknesses in the length direction of the light emitting element LD. In an example, the first semiconductor layer 11 may have a thickness relatively thicker than that of the second semiconductor layer 13 along the length direction of the light emitting element LD. Accordingly, the active layer 12 of the light emitting element LD may be located more adjacent to the upper surface of the second semiconductor layer 13 than the lower surface of the first semiconductor layer 11.

Although it is illustrated that each of the first semiconductor layer 11 and the second semiconductor layer 13 is configured with one layer, the present disclosure is not limited thereto. In one or more embodiments, each of the first semiconductor layer 11 and the second semiconductor layer 13 may further include at least one layer, e.g., a clad layer and/or a Tensile Strain Barrier Reducing (TSBR) layer according to the material of the active layer 12. The TSBR layer may be a strain reducing layer disposed between semiconductor layers having different lattice structures to perform a buffering function for reducing a lattice constant difference. The TSBR may be configured with a p-type semiconductor layer such as p-GAInP, p-AlInP or p-AlGaInP, but the present disclosure is not limited thereto.

In one or more embodiments, the light emitting element LD may further include a contact electrode (hereinafter, referred to as a “first contact electrode”) disposed on the top of the second semiconductor layer 13, in addition to the first semiconductor layer 11, the active layer 12, and the second semiconductor layer 13, which are described above. In one or more embodiments, the light emitting element LD may further include another contact electrode (hereinafter, referred to as a “second contact electrode”) disposed at one end of the first semiconductor layer 11.

Each of the first and second contact electrodes may be an ohmic contact electrode, but the present disclosure is not limited thereto. In one or more embodiments, each of the first and second contact electrodes may be a Schottky contact electrode. The first and second contact electrodes may include a conductive material.

In one or more embodiments, the light emitting element LD may further include an insulative film 14 (or insulating film). However, in one or more embodiments, the insulative film 14 may be omitted, and may be provided to cover only portions of the first semiconductor layer 11, the active layer 12, and the second semiconductor layer 13.

The insulative film 14 can prevent an electrical short circuit that may occur when the active layer 12 is in contact with a conductive material in addition to the first semiconductor layer 11 and the second semiconductor layer 13. Also, the insulative film 14 reduces or minimizes a surface defect of the light emitting element LD, thereby improving the lifetime and light emission efficiency of the light emitting element LD. Also, when a plurality of light emitting elements LD are densely disposed, the insulative film 14 can prevent an unwanted short circuit that may occur between the light emitting elements LD. Whether the insulative film is provided is not limited as long as the active layer 12 can prevent occurrence of a short circuit with external conductive material.

The insulative film 14 may be provided in a shape to be around (e.g., partially or entirely surrounding) an outer surface (e.g., an outer peripheral or circumferential surface) of the light emitting stack structure including the first semiconductor layer 11, the active layer 12, and the second semiconductor layer 13.

Although a case where the insulative film 14 is provided in a shape entirely surrounding an outer surface (e.g., an outer peripheral or circumferential surface) of each of the first semiconductor layer 11, the active layer 12, and the second semiconductor layer 13 is described in the above-described embodiment, the present disclosure is not limited thereto.

The insulative film 14 may include a transparent insulating material. For example, the insulative film 14 may include at least one insulating material selected from the group consisting of silicon oxide (SiOₓ), silicon nitride (SiNₓ), silicon oxynitride (SiOₓN_{y}), aluminum oxide (AlOₓ), titanium dioxide (TiO₂), hafnium oxide (HfOₓ), titanium strontium oxide (SrTiOₓ), cobalt oxide (CoₓO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), vanadium nitride (VN), and the like. However, the present disclosure is not limited thereto, and various materials having insulating properties may be used as the material of the insulative film 14.

The insulative film 14 may be provided in the form of a single layer or be provided in the form of a multi-layer including at least two layers.

The above-described light emitting element LD may be used as a light emitting source (or light source) for various display devices. The light emitting element LD may be manufactured through a surface treatment process. For example, when a plurality of light emitting elements LD are mixed in a liquid solution (or solvent) to be supplied to each pixel area (e.g., an emission area of each pixel or an emission area of each sub-pixel), each light emitting element LD may be surface-treated such that the light emitting elements LD are not unequally condensed in the solution but equally dispersed in the solution.

A light emitting unit (or light emitting device) including the above-described light emitting element LD may be used in various types of devices that require a light source, including a display device. When a plurality of light emitting elements LD are disposed in an emission area of each pixel of a display panel, the light emitting elements LD may be used as a light source of the pixel. However, the application field of the light emitting element LD is not limited to the above-described example. For example, the light emitting element LD may be used for other types of electronic devices that require a light source, such as a lighting device.

However, this is merely illustrative, and a light emitting element applied to display devices in accordance with embodiments of the present disclosure is not limited thereto. For example, the light emitting element may be a flip chip type micro light emitting diode or an organic light emitting element including an organic emitting layer.

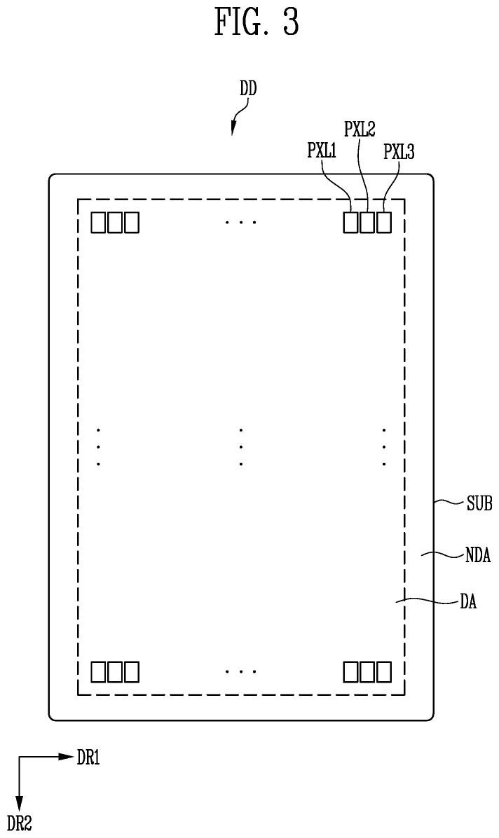

FIG. 3 is a schematic plan view illustrating a display device in accordance with one or more embodiments of the present disclosure.

Referring to FIGS. 1, 2, and 3, the display device DD may include a substrate SUB, pixels PXL1, PXL2, and PXL3 that are provided on the substrate SUB and each includes at least one light emitting element LD, a driving unit that is provided on the substrate SUB and drives the pixels PXL1, PXL2, and PXL3, and a line unit that connects the pixels PXL1, PXL2, and PXL3 to the driving unit.

The substrate SUB may include the display area DA and a non-display area NDA along an edge or periphery of the display area DA.

The display area DA may be an area in which the pixels PXL1, PXL2, and PXL3 for displaying an image are provided. The non-display area NDA may be an area in which the driving unit for driving the pixels PXL1, PXL2, and PXL3 and a portion of the line unit that connects the pixels PXL1, PXL2, and PXL3 to the driving unit are provided.

The non-display area NDA may be located adjacent to the display area DA. The non-display area NDA may be provided at at least one side of the display area DA. In an example, the non-display area NDA may be around (e.g., may surround) a periphery (or edge) of the display device DA.

The line unit may electrically connect the pixels PXL1, PXL2, and PXL3 to the driving unit. The line unit may provide signals to the pixels PXL1, PXL2, and PXL3, and include signal lines, e.g., a fan-out line connected to a scan line, a data line, an emission control line, and the like, which are connected to each of the pixels PXL1, PXL2, and PXL3.

The substrate SUB may include a transparent insulating material to enable light to be transmitted therethrough. The substrate SUB may be a rigid substrate or a flexible substrate.

The pixels PXL1, PXL2, and PXL3 may include a first pixel PXL1, a second pixel PXL2, and a third pixel PXL3. In one or more embodiments, the first pixel PXL1 may be a red pixel, the second pixel PXL2 may be a green pixel, and the third pixel PXL3 may be a blue pixel. However, the present disclosure is not limited thereto, and each of the pixels PXL1, PXL2, and PXL3 may emit light of another color instead of red, green, and blue.

Each of the pixels PXL1, PXL2, and PXL3 may include at least one light emitting element LD driven by a scan signal and a data signal. The light emitting element LD may have a small size to a degree of a nano scale (or nanometers) to a micro scale (micrometers), and may be connected in parallel to light emitting elements disposed adjacent thereto. However, the present disclosure is not limited thereto. The light emitting element LD may constitute a light source of each of the pixels PXL1, PXL2, and PXL3.

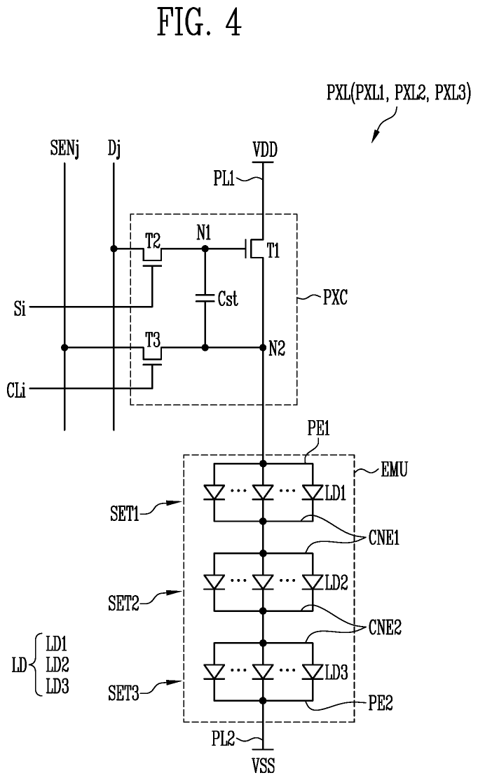

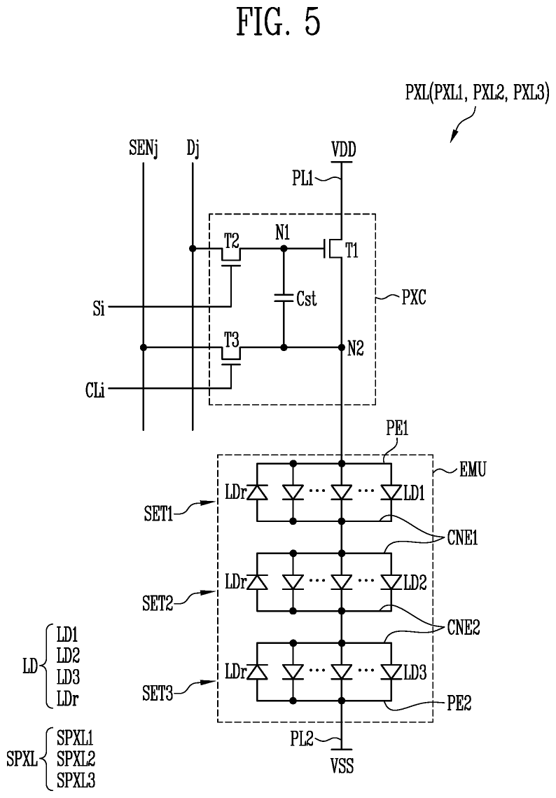

FIG. 4 is a circuit diagram illustrating an example of the pixel included in the display device shown in FIG. 3. FIG. 5 is a circuit diagram illustrating an example of the pixel included in the display device shown in FIG. 3.

In the following embodiment, when a first pixel PXL1, a second pixel PXL2, and a third pixel PXL3 are inclusively designated, each of the first pixel PXL1, the second pixel PXL2, and the third pixel PXL3 will be referred to as a “pixel PXL.”

Referring to FIGS. 1, 2, 3, and 4, the pixel PXL may include a pixel circuit PXC and a light emitting unit EMU (or light emitting part).

The light emitting unit EMU may include light emitting elements LD connected between a first power line PL1 and a second power line PL2. The light emitting unit EMU may include serial stages SET1, SET2, and SET3 connected in series to each other between the first power line PL1 and the second power line PL2.

A first serial stage SET1 may include first light emitting elements LD electrically connected between a first pixel electrode PE1 and a first connection electrode CNE1. For example, a first end portion EP1 of the first light emitting element LD1 may be connected to the first pixel electrode PE1, and a second end portion EP2 of the first light emitting element LD1 may be connected to the first connection electrode CNE1. The first light emitting elements LD1 may be connected in parallel between the first pixel electrode PE1 and the first connection electrode CNE1.

In one or more embodiments, as shown in FIG. 4, the first light emitting elements LD1 may be connected in the same direction (e.g., a forward direction). In one or more embodiments, as shown in FIG. 5, at least one reverse light emitting element LDr may be further connected in the first serial stage SET1. The reverse light emitting element LDr may be connected between the first pixel electrode PE1 and the first connection electrode CNE1 in the opposite direction of the direction in which the first light emitting elements LD1 are connected. Although a driving voltage in the forward direction is applied, the reverse light emitting element LDr maintains an inactivated state, and accordingly, no current substantially flows through the reverse light emitting element LDr.

A second serial stage SET2 may include second light emitting elements LD2 connected between the first connection electrode CNE1 and a second connection electrode CNE2. For example, a first end portion EP1 of the second light emitting element LD2 may be connected to the first connection electrode CNE1, and a second end portion EP2 of the second light emitting element LD2 may be connected to the second connection electrode CNE2. The second light emitting elements LD2 may be connected in parallel between the first connection electrode CNE1 and the second connection electrode CNE2.

In one or more embodiments, as shown in FIG. 4, the second light emitting elements LD2 may be connected in the forward direction. In one or more embodiments, as shown in FIG. 5, at least one reverse light emitting element LDr may be further connected in the second serial stage SET2.

The second serial stage SET2 and the first serial stage SET1 may be connected in series.

A third serial stage SET3 may include third light emitting elements LD3 connected between the second connection electrode CNE2 and a second pixel electrode PE2. For example, a first end portion EP1 of the third light emitting element LD3 may be connected to the second connection electrode CNE2, and a second end portion EP2 of the third light emitting element LD3 may be connected to the second pixel electrode PE2. The third light emitting elements LD3 may be connected in parallel between the second connection electrode CNE2 and the second pixel electrode PE2.

In one or more embodiments, as shown in FIG. 4, the third light emitting elements LD3 may be connected in forward direction. In one or more embodiments, as shown in FIG. 5, at least one reverse light emitting element LDr may be further connected in the third serial stage SET3.

The third serial stage SET3 may be connected in series to the second serial stage SET2 and the first serial stage SET1.

In one or more embodiments, the first pixel electrode PE1 may be an anode electrode of the light emitting unit EMU, and the second pixel electrode PE2 may be a cathode electrode of the light emitting unit EMU.

The first serial stage SET1 and the second serial stage SET2 may be electrically connected to each other through the first connection electrode CNE1. The second serial stage SET2 and the third serial stage SET3 may be electrically connected to each other through the second connection electrode CNE2.

As described above, the light emitting unit EMU of the pixel PXL, which includes the light emitting elements LD connected in a series/parallel hybrid structure, can easily control driving current/voltage conditions to be suitable for specifications of a product to which the light emitting unit EMU is applied.

In particular, the light emitting unit EMU of the pixel PXL, which includes the light emitting elements LD connected in the series/parallel hybrid structure, can decrease a driving current, as compared with a light emitting unit having a structure in which the light emitting elements LD are connected only in parallel. Also, the light emitting unit EMU of the pixel PXL, which includes the light emitting elements LD connected in the series/parallel hybrid structure, can decrease a driving voltage applied between both ends of the light emitting unit EMU, as compared with a light emitting unit having a structure in which the light emitting elements LD are all connected only in series. In addition, when the light emitting elements LD are all connected only in series, a dark spot defect may be caused while a path through which a driving current can flow in the pixel PXL is blocked, when at least one of the light emitting elements connected in series is not completely connected in the forward direction (or when the reverse light emitting element LDr is included). On the other hand, although some light emitting elements LD are not connected in the forward direction (or the reverse light emitting element LDr is included) or a defect occurs some light emitting elements LD inside each serial stage when the light emitting elements LD are connected in the series/parallel hybrid structure, a driving current can flow through another light emitting element LD of the corresponding serial stage. Accordingly, a defect of the pixel PXL can be prevented or reduced.

The pixel circuit PXC may be connected to a scan line Si (i is a positive integer) and a data line Dj (j is a positive integer) of the pixel PXL. Also, the pixel circuit PXC may be connected to a control line CLi and a sensing line SENj of the pixel PXL. In an example, when the pixel PXL may be disposed on an ith row and a jth column of the display area DA, the pixel circuit PXC of the pixel PXL may be connected an ith scan line Si, a jth data line Dj, an ith control line CLi, and a jth sensing line SENj of the display area DA.

In one or more embodiments, the pixel circuit PXC may include first to third transistors T1 to T3 and a storage capacitor Cst.

The first transistor T1 may be a driving transistor for controlling a driving current applied to the light emitting unit EMU. The first transistor T1 may be connected between a first driving power source VDD and the light emitting element LD. A gate electrode of the first transistor T1 may be connected to a first node N1.

The first transistor T1 may control an amount of driving current applied from the first driving power source VDD to the light emitting unit EMU through a second node N2 according to a voltage applied to the first node N1.

The second transistor T2 may be a switching transistor to select a pixel PXL in response to a scan signal and activates the pixel PXL. The second transistor T2 may be connected to the data line Dj and the first node N1. A gate electrode of the second transistor T2 may be connected to the scan line Si.

The second transistor T2 may be turned on by a scan signal supplied to the scan line Si, and transfer a data signal to the gate electrode of the first transistor T1.

The third transistor T3 may connect the first transistor T1 to the sensing line SENj, to acquire a sensing signal through the sensing line SENj and to detect a characteristic of the pixel PXL, including a threshold voltage of the first transistor T1, and the like, by using the sensing signal. Information on the characteristic of the pixel PXL may be used to convert image data such that a characteristic deviation between pixels can be compensated.

The third transistor T3 may be connected between the sensing line SENj and the second node N2. A gate electrode of the third transistor T3 may be connected to the control line CLi.

In one or more embodiments, a voltage of an initialization power source may be provided through the sensing line SENj in a suitable period (e.g., a predetermined period). The third transistor T3 may be turned on when a sensing control signal is supplied from the control line CLi, to transfer the voltage of the initialization power source to the second node N2. Accordingly, a voltage stored in the storage capacitor Cst connected to the second node N2 may be initialized.

The storage capacitor Cst may be connected between the first node N1 and the second node N2. The storage capacitor Cst may charge a data voltage corresponding to the data signal supplied to the first node N1 during one frame period. Accordingly, the storage capacitor Cst may store a voltage corresponding to the difference between a voltage of the gate electrode of the first transistor T1 and a voltage of the second node N2.

In one or more embodiments of the present disclosure, a three-series structure (i.e., the first, second, and third serial stages SET1, SET2, and SET3) as shown in FIGS. 4 and 5 may be applied to the light emitting unit EMU by considering the resolution of the display device DD, the area of an emission area of the pixel PXL, and the like. Hereinafter, embodiments will be described based on the three-series structure.

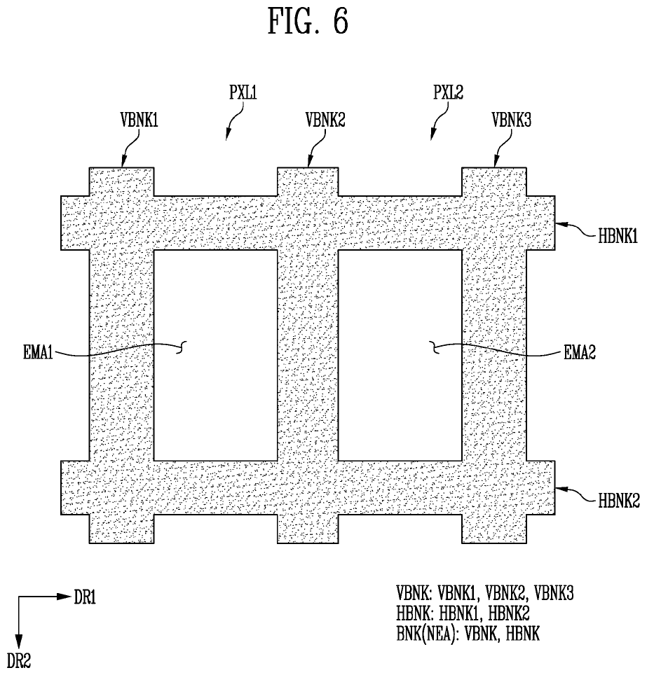

FIGS. 6 to 8 are schematic plan views illustrating an example of the pixels included in the display device shown in FIG. 3.

FIG. 6 is a view illustrating emission areas EMA1 and EMA2 of first and second pixels PXL1 and PXL2 and a non-emission area NEA, and mainly illustrates a bank BNK.

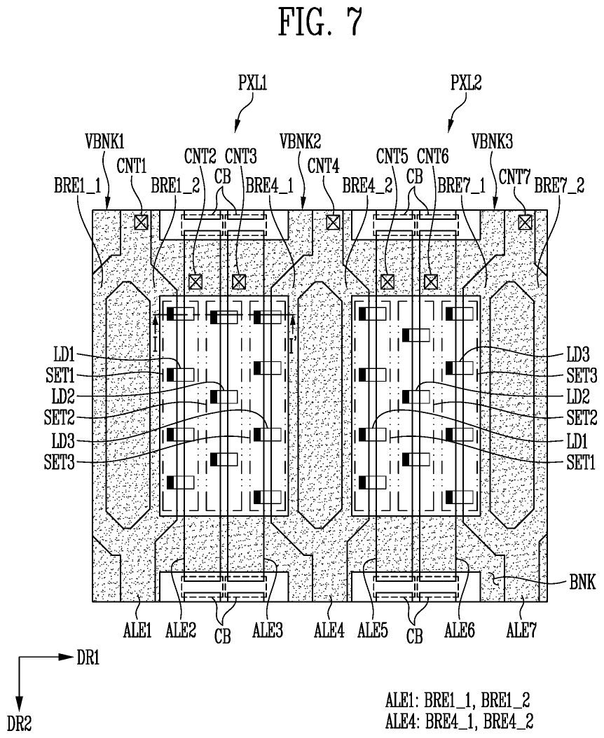

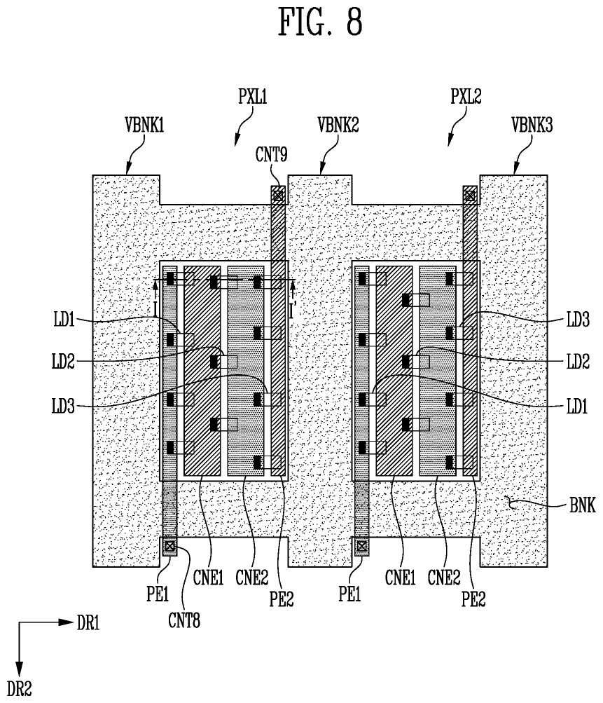

FIGS. 7 and 8 are views illustrating some components included in the first and second pixels PXL1 and PXL2, based on the bank BNK shown in FIG. 6. FIG. 7 is a view mainly illustrating light emitting elements LD1, LD2, and LD3 and alignment electrodes ALE1 to ALE7, and FIG. 8 is a view mainly illustrating the light emitting elements LD1, LD2, and LD3, pixel electrodes PE1 and PE2, and connection electrodes CNE1 and CNE2.

Referring to FIGS. 6 to 8, the display device DD may include a bank BNK, alignment electrodes ALE1 to ALE7, light emitting elements LD1, LD2, and LD3, pixel electrodes PE1 and PE2, and connection electrodes CNE1 and CNE2 to constitute pixels PXL1 and PXL2.

As shown in FIG. 6, the bank BNK may partition a first pixel PXL1 and a second pixel PXL2. The first pixel PXL1 may include a first emission area EMA1, and the second pixel PXL2 may include a second emission area EMA2. Each of the first and second emission areas EMA1 and EMA2 is an area in which light is emitted, and may include light emitting elements LD1, LD2, and LD2.

Each of the first emission area EMA1 and the second emission area EMA2 may correspond to an opening defined by the bank BNK.

In one or more embodiments, the bank BNK may form a space in which a fluid can be accommodated. For example, during a manufacturing process, ink including the light emitting elements LD1, LD2, and LD3 may be provided in the space in which the fluid can be accommodated.

A non-emission area NEA may be an area substantially corresponding to the bank BNK. When viewed on a plane, the bank BNK may surround each of the first emission area EMA1 and the second emission area EMA2. For example, the bank BNK may include horizontal extension parts HBNK and vertical extension parts VBNK.

In one or more embodiments, the bank BNK may include a first horizontal extension part HBNK1 and a second horizontal extension part HBNK2, which extend in a first direction DR1 (e.g., a horizontal direction). The first horizontal extension part HBNK1 and the second horizontal extension part HBNK2 may be spaced from each other in a second direction DR2 (e.g., a vertical direction).

In one or more embodiments, the bank BNK may include a first vertical extension part VBNK1, a second vertical extension part VBNK2, and a third vertical extension part VBNK3, which extend in the second direction DR2. The first vertical extension part VBNK1, the second vertical extension part VBNK2, and the third vertical extension part VBNK3 may be spaced from each other in the first direction DR1.

The first emission area EMA1 may be formed (e.g., defined) by an area in which the first vertical extension part VBNK1, the second vertical extension part VBNK2, the first horizontal extension part HBNK1, and the second horizontal extension part HBNK2 cross each other. Similarly, the second emission area EMA2 may be formed (e.g., defined) by an area in which the second vertical extension part VBNK2, the third vertical extension part VBNK3, the first horizontal extension part HBNK1, and the second horizontal extension part HBNK2 cross each other. Therefore, the first emission area EMA1 and the second emission area EMA2 may be adjacent to each other with the second vertical extension part VBNK2 interposed therebetween.

As the resolution of the display device DD increases, the number of pixels included in the same area increases. This means that the area of the emission areas EMA1 and EMA2 decreases, and it is substantially difficult to constitute four or more serial stages by using light emitting elements. Therefore, as shown in FIGS. 7 and 8, each of the emission areas EMA1 and EMA2 may include three serial stages SET1, SET2, and SET3.

In one or more embodiments, as shown in FIG. 7, the first pixel PXL1 may include a first alignment electrode ALE1, a second alignment electrode ALE2, a third alignment electrode ALE3, and a fourth alignment electrode ALE4. The second pixel PXL2 may include the fourth alignment electrode ALE4, a fifth alignment electrode ALE5, a sixth alignment electrode ALE6, and a seventh alignment electrode ALE7. In other words, the first pixel PXL1 and the second pixel PXL2 may share the fourth alignment electrode ALE4.

The first to seventh alignment electrodes ALE1 to ALE7 may be sequentially arranged while being spaced from each other along the first direction DR1. The first to seventh alignment electrodes ALE1 to ALE7 may be disposed at a lower portion of the bank BNK.

In one or more embodiments, the first to seventh alignment electrodes ALE1 to ALE7 may be electrodes for alignment the light emitting elements LD1, LD2, and LD3. For example, an electric field may be formed between the first alignment electrode ALE1 and the second alignment electrode ALE2, and first light emitting elements LD1 may be aligned on the first alignment electrode ALE1 and the second alignment electrode ALE2, based on the electric field. For example, the light emitting elements LD1, LD2, and LD3 may be moved (or rotated) by a force (e.g., a dielectrophoresis (DEP) force) according to the electric field, to be aligned (or disposed) on the alignment electrodes.

In one or more embodiments, each of the first to seventh alignment electrodes ALE1 to ALE7 may be supplied (or provided) with a first alignment signal or a second alignment signal in a process of aligning the light emitting elements LD1, LD2, and LD3 (hereinafter, referred to as an alignment process). For example, different alignment signals may be applied to alignment electrodes adjacent to each other. The first alignment signal and the second alignment signal may have different waveforms, different potentials, and/or different phases. For example, the first alignment signal may be an AC signal, and the second alignment signal may be a ground signal. However, the present disclosure is not necessarily limited to the above-described example.

In one or more embodiments, the first alignment electrode ALE1 may overlap with the first vertical extension part VBNK1 of the bank BNK and the first emission area EMA1. In one or more embodiments, a portion of the first alignment electrode ALE1 may also overlap with an emission area at the left of the first vertical extension part VBNK1.

In one or more embodiments, the first alignment electrode ALE1 may be connected to a first signal line thereunder through a first contact hole CNT1, and the first alignment signal may be provided to the first alignment electrode ALE1 through the first signal line in the alignment process. Therefore, an alignment signal provided to an electrode (e.g., the first alignment electrode ALE1) overlapping with the first vertical extension part VBNK1 may be unified.

The second alignment electrode ALE2 may be adjacent to the first alignment electrode ALE1, and extend in the second direction DR2. The second alignment electrode ALE2 may overlap with the first emission area EMA1.

In one or more embodiments, the second alignment electrode ALE2 may be connected to a second signal line thereunder through a second contact hole CNT2, and the second alignment signal may be provided to the second alignment electrode ALE2 through the second signal line in the alignment process.

The third alignment electrode ALE3 may be adjacent to the second alignment electrode ALE2, and extend in the second direction DR2. The third alignment electrode ALE3 may overlap with the first emission area EMA1.

In one or more embodiments, the third alignment electrode ALE3 may be connected to the first signal line through a third contact hole CNT3, and the first alignment signal may be provided to the third alignment electrode ALE3 through the first signal line during the alignment process.

In one or more embodiments, the second alignment electrode ALE2 and the third alignment electrode ALE3 may include cut end portions CB. For example, after the alignment process is ended, the second alignment electrode ALE2 and the third alignment electrode ALE3 may have a floating state as dummy electrodes due to the cut end portions CB.

The fourth alignment electrode ALE4 may overlap with the second vertical extension part VBNK2 of the bank BNK, the first emission area EMA1, and the second emission area EMA2. In one or more embodiments, the fourth alignment electrode ALE4 may be connected to a second signal line thereunder through a fourth contact hole CNT4, and the second alignment signal may be provided to the fourth alignment electrode ALE4 in the alignment process. Therefore, an alignment signal provided to an electrode (e.g., the fourth alignment electrode ALE4) overlapping with the second vertical extension part VBNK2 may be unified.

In one or more embodiments, a planar shape of the first alignment electrode ALE1 may be substantially similar (e.g., identical) to a planar shape of the fourth alignment electrode ALE4. However, different alignment signals may be supplied to the first alignment electrode ALE1 and the fourth alignment electrode ALE4 so as to implement an arrangement of the light emitting elements LD1, LD2, and LD3 having a three-series structure.

In one or more embodiments, each of the first alignment electrode ALE1 and the fourth alignment electrode ALE4 may include a first branch electrode BRE1_1 or BRE4_1 and a second branch electrode BRE1_2 or BRE4_2, which branch off while overlapping with the bank BNK to extend in the second direction DR2.

The second branch electrode BRE1_2 of the first alignment electrode ALE1 may overlap with the first emission area EMA1.

The first branch electrode BRE4_1 of the fourth alignment electrode ALE4 may overlap with the first emission area EMA1, and the second branch electrode BRE4_2 of the fourth alignment electrode ALE4 may overlap with the second emission area EMA2.

The same first alignment signal may be provided to the first branch electrode BRE1_1 and the second branch electrode BRE1_2 of the first alignment electrode ALE1. The same second alignment signal may be provided to the first branch electrode BRE4_1 and the second branch electrode BRE4_2 of the fourth alignment electrode ALE4.

The fifth alignment electrode ALE5 may be adjacent to the fourth alignment electrode ALE4, and extend in the second direction DR2. The fifth alignment electrode ALE5 may overlap with the second emission area EMA2.

In one or more embodiments, the fifth alignment electrode ALE5 may be connected to the first signal line through a fifth contact hole CNT5, and the first alignment signal may be provided to the fifth alignment electrode ALE5 through the first signal line in the alignment process.

The sixth alignment electrode ALE6 may be adjacent to the fifth alignment electrode ALE5, and extend in the second direction DR2. The sixth alignment electrode ALE6 may overlap with the second emission area EMA2.

In one or more embodiments, the sixth alignment electrode ALE6 may be connected to the second signal line through a sixth contact hole CNT6, and the second alignment signal may be provided to the sixth alignment electrode ALE6 through the second signal line in the alignment process.

In one or more embodiments, the fifth alignment electrode ALE5 and the sixth alignment electrode ALE6 may include cut end portions CB. The fifth alignment electrode ALE5 and the sixth alignment electrode ALE6 may have the floating state as dummy electrodes due to the cut end portions CB.

The seventh alignment electrode ALE7 may overlap with the third vertical extension part VBNK3 of the bank BNK and the second emission area EMA2. In one or more embodiments, a portion of the seventh alignment electrode ALE7 may also overlap with an emission area at the right of the third vertical extension part VBNK3.

In one or more embodiments, the seventh alignment electrode ALE7 may be connected to the first signal line through a seventh contact hole CNT7, and the first alignment signal may be provided to the seventh alignment electrode ALE7 through the first signal line in the alignment process.

As described above, in the alignment process, the first alignment signal may be provided to odd-numbered alignment electrodes ALE1, ALE3, ALE5, and ALE7, and the second alignment signal may be provided to even-numbered alignment electrodes ALE2, ALE4, and ALE6. However, this is merely illustrative. The second alignment signal may be provided to the odd-numbered alignment electrodes ALE1, ALE3, ALE5, and ALE7, and the first alignment signal may be provided to the even-numbered alignment electrodes ALE2, ALE4, and ALE6.

Both the first emission area EMA1 and the second emission area EMA2 may include first light emitting elements LD1 forming a first serial stage SET1, second light emitting elements LD2 forming a second serial stage SET2, and third light emitting elements LD3 forming a third serial stage SET3. In one or more embodiments, arrangement forms of light emitting elements LD1, LD2, and LD3 in the first emission area EMA1 and the second emission area EMA2 may be substantially identical or similar to each other.

In the first emission area EMA1, first light emitting elements LD1 may overlap with the first alignment electrode ALE1 and the second alignment electrode ALE2. For example, the first light emitting elements LD1 may be arranged on the second branch electrode BRE1_2 of the first alignment electrode ALE1 and the second alignment electrode ALE2.

In the first emission area EMA1, second light emitting elements LD2 may overlap with the second alignment electrode ALE2 and the third alignment electrode ALE3. For example, the second light emitting elements LD2 may be arranged on the second alignment electrode ALE2 and the third alignment electrode ALE3.

In the first emission area EMA1, third light emitting elements LD3 may overlap with the third alignment electrode ALE3 and the fourth alignment electrode ALE4. For example, the third light emitting elements LD3 may be arranged on the third alignment electrode ALE3 and the first branch electrode BRE4_1 of the fourth alignment electrode ALE4.

In the second emission area EMA2, first light emitting elements LD1 may overlap with the fourth alignment electrode ALE4 and the fifth alignment electrode ALE5. For example, the first light emitting elements LD1 may be arranged on the second branch electrode BRE4_2 of the fourth alignment electrode ALE4 and the fifth alignment electrode ALE5.

Like the first emission area EMA1, in the second emission area EMA2, second light emitting elements LD2 may overlap with the fifth alignment electrode ALE5 and the sixth alignment electrode ALE6, and third light emitting elements LD3 may overlap with the sixth alignment electrode ALE6 and the seventh alignment electrode ALE7.

As described above, alignment electrodes (e.g., first, fourth, and seventh electrodes ALE1, ALE4, and ALE7) are disposed such that only one alignment signal is transferred to an alignment electrode overlapping with each of the vertical extension parts VBNK of the bank BNK (e.g., such that the first alignment signal is transferred to the first alignment electrode ALE1 and the second alignment signal is transferred to the fourth alignment electrode ALE4). Thus, the generation of an electric field under each of the vertical extension parts VBNK can be suppressed. Accordingly, when the light emitting elements LD1, LD2, and LD3 forming the first to third serial stages SET1 to SET3 are arranged, an arrangement defect in which light emitting elements are disposed on the vertical extension parts VBNK while being separated from positions thereof can be reduced or minimized.

As shown in FIG. 8, each of the first pixel PXL1 and the second pixel PXL2 may include a first pixel electrode PE1, a second pixel electrode PE2, a first connection electrode CNE1, and a second connection electrode CNE2. A first pixel electrode PE1, a second pixel electrode PE2, a first connection electrode CNE1, and a second connection electrode CNE2 of the second pixel PXL2 are substantially identical to a first pixel electrode PE1, a second pixel electrode PE2, a first connection electrode CNE1, and a second connection electrode CNE2 of the first pixel PXL1, and therefore, the first pixel PXL1 will be mainly described.

In one or more embodiments, the first pixel electrode PE1, the second pixel electrode PE2, the first connection electrode CNE1, and the second connection electrode CNE2 may be disposed on the alignment electrodes ALE1 to ALE7 and the light emitting elements LD1, LD2, and LD3.

In one or more embodiments, the first pixel electrode PE1, the second pixel electrode PE2, the first connection electrode CNE1, and the second connection electrode CNE2 may be sequentially arranged along the first direction DR1 in the first emission area EMA1.

A portion of the first pixel electrode PE1 may overlap with the bank BNK. Also, the first pixel electrode PE1 may overlap with a portion of the first alignment electrode ALE1. For example, the first pixel electrode PE1 may overlap with a portion of the second branch electrode BRE1_2 of the first alignment electrode ALE1. The first pixel electrode PE1 may be electrically connected to a transistor (e.g., the first transistor T1 shown in FIG. 4) thereunder through an eighth contact hole CNT8 at a portion not overlapping with the first alignment electrode ALE1. Therefore, the first pixel electrode PE1 may be insulated from the first alignment electrode ALE1.

The first connection electrode CNE1 may be disposed in the first emission area EMA1. The first light emitting elements LD1 may be connected in parallel to the first pixel electrode PE1 and the first connection electrode CNE1. For example, the first pixel electrode PE1 may be electrically connected to a first end portion of the first light emitting element LD1, and the first connection electrode CNE1 may be electrically connected to a second end portion of the first light emitting element LD1.

In one or more embodiments, the first connection electrode CNE1 may overlap with a portion of the second alignment electrode ALE2. The first connection electrode CNE1 and the second alignment electrode ALE2 may be insulated from each other. For example, the second contact hole CNT2 of the second alignment electrode ALE2 may be formed while avoiding the first connection electrode CNE1.

The second connection electrode CNE2 may be disposed in the first emission area EMA1. The second light emitting elements LD2 may be connected in parallel to the first connection electrode CNE1 and the second connection electrode CNE2. For example, the first connection electrode CNE1 may be electrically connected to a first end portion of the second light emitting element LD2, and the second connection electrode CNE2 may be electrically connected to a second end portion of the second light emitting element LD2.

In one or more embodiments, the second connection electrode CNE2 may overlap with a portion of the third alignment electrode ALE3. The second connection electrode CNE2 and the third alignment electrode ALE3 may be insulated from each other. For example, the third contact hole CNT3 of the third alignment electrode ALE3 may be formed while avoiding the second connection electrode CNE2.

The second pixel electrode PE2 may be adjacent to the second connection electrode CNE2. A portion of the second pixel electrode PE2 may overlap with the bank BNK. Also, the second pixel electrode PE2 may overlap with a portion of the fourth alignment electrode ALE4. For example, the second pixel electrode PE2 may overlap with a portion of the first branch electrode BRE4_1 of the fourth alignment electrode ALE4.

The second pixel electrode PE2 may be electrically connected to the second power line (PL2 shown in FIG. 4) thereunder through a ninth contact hole CNT9 at a portion not overlapping with the fourth alignment electrode ALE4. Therefore, the second pixel electrode PE2 may be insulated from the fourth alignment electrode ALE4. However, this is merely illustrative, and one of the second pixel electrode PE2 of the first pixel PXL1 and the first pixel electrode PE1 of the second pixel PXL2 may be connected to the fourth alignment electrode ALE4 thereunder through a contact hole.

For example, the second pixel electrode PE2 of the first pixel PXL1 may be connected to the fourth alignment electrode ALE4 through a contact hole, and the first pixel electrode PE1 of the second pixel PXL2 may be insulated from the fourth alignment electrode ALE4. The fourth alignment electrode ALE4 may serve as a bridge electrode, and the second pixel electrode PE2 of the first pixel PXL1 and the second power line (PL2 shown in FIG. 4) may be electrically connected to each other through the fourth alignment electrode ALE4.

In another example, the first pixel electrode PE1 of the second pixel PXL2 may be connected to the fourth alignment electrode ALE4 through a contact hole, and the second pixel electrode PE2 of the first pixel PXL1 may be insulated from the fourth alignment electrode ALE4. The fourth alignment electrode ALE4 may serve as a bridge electrode, and the first pixel electrode PE1 of the second pixel PXL2 and the first transistor (T1 shown in FIG. 4) of the second pixel PXL2 may be electrically connected to each other through the fourth alignment electrode ALE4.

As described above, in order to prevent a driving error of the pixels PXL1 and PXL2, caused by the fourth alignment electrode ALE4 overlapping with the second pixel electrode PE2 of the first emission area EMA1 and the first pixel electrode PE1 of the second emission area EMA2, at least one of the second pixel electrode PE2 of the first emission area EMA1 and the first pixel electrode PE1 of the second emission area EMA2 may be insulated from the fourth alignment electrode ALE4.

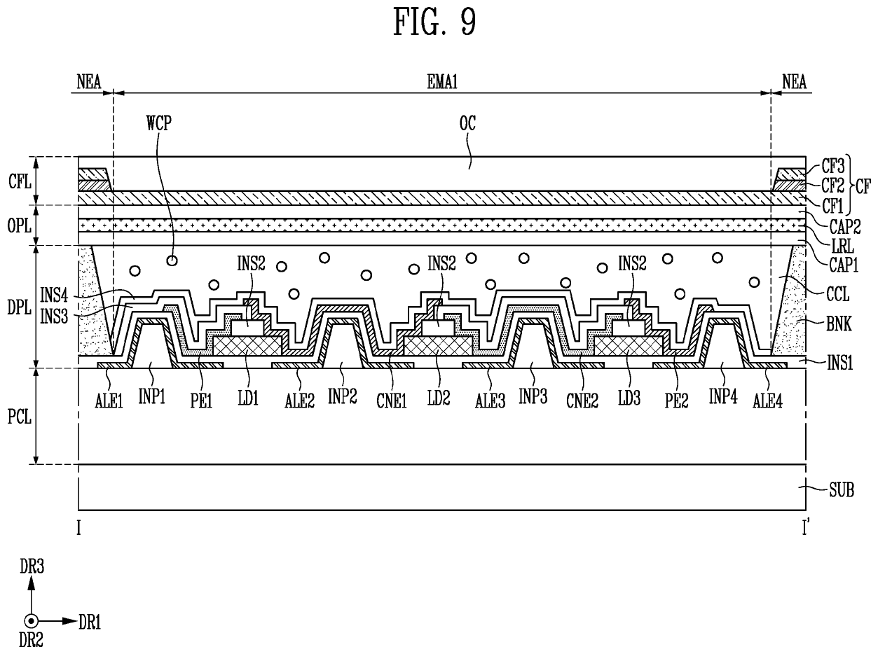

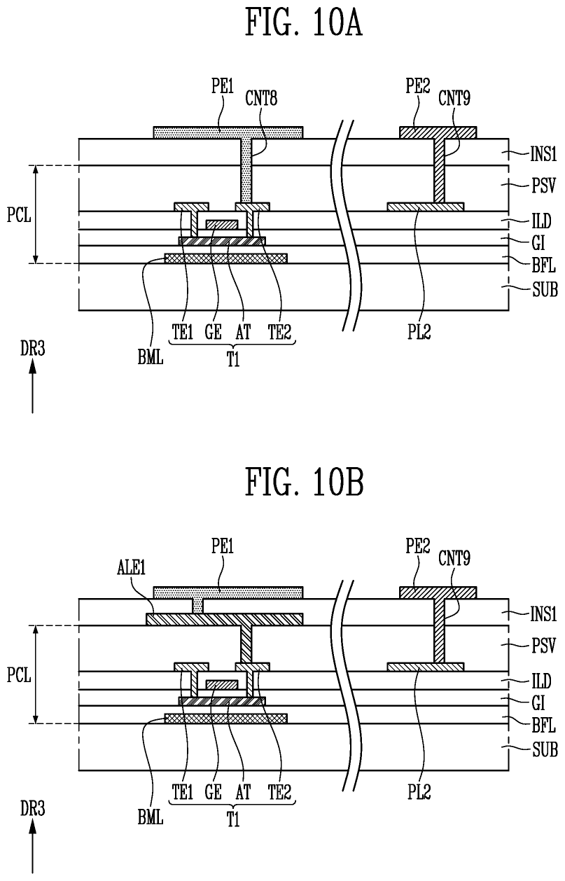

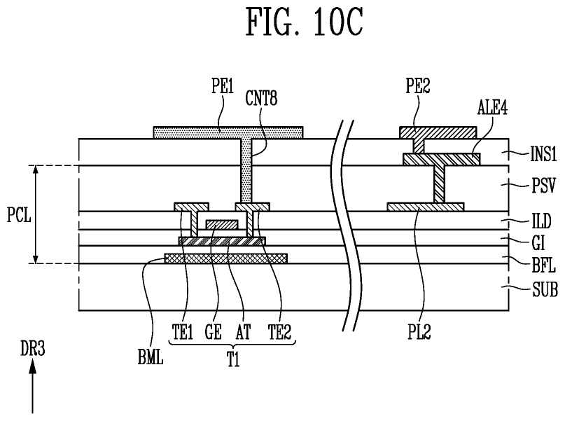

FIG. 9 is a schematic sectional view illustrating an example taken along the line I-I′ shown in FIGS. 7 and 8. FIGS. 10A to 10C are schematic sectional views illustrating examples of a partial area shown in FIG. 8.

Referring to FIGS. 6, 7, 8, 9, 10A, 10B, and 10C, the first pixel PXL1 may include a substrate SUB, a pixel circuit layer PCL, a display element layer DPL, an optical layer OPL, and a color filter layer CFL.

The substrate SUB may form a base member of the display device DD. The substrate SUB may be a rigid or flexible substrate or film. The substrate SUB may include a transparent insulating material to enable light to be transmitted therethrough.

The substrate SUB may be a rigid substrate. For example, the rigid substrate may be one of a glass substrate, a quartz substrate, a glass ceramic substrate, and a crystalline glass substrate.

Also, the substrate SUB may be a flexible substrate. The flexible substrate may be one of a film substrate and a plastic substrate, which include a polymer organic material. However, the material constituting the substrate SUB may be variously changed, and include fiber reinforced plastic (FRP), and the like.

The pixel circuit layer PCL may be disposed on the substrate SUB. As shown in FIGS. 10A, 10B, and 10C, the pixel circuit layer PCL may include a lower auxiliary electrode BML, a buffer layer BFL, a first transistor T1, a gate insulating layer GI, an interlayer insulating layer ILD, and a protective layer PSV. For convenience of description, only the first transistor T1 from among circuit elements is illustrated in FIGS. 10A, 10B, and 10C.

The lower auxiliary electrode BML may be disposed on the substrate SUB. The lower auxiliary electrode BML may serve as a path through which an electrical signal is moved. In one or more embodiments, a portion of the lower auxiliary electrode BML may overlap with the first transistor T1 when viewed on a plane.

The buffer layer BFL may be disposed on the substrate SUB. The buffer layer BFL may cover the lower auxiliary electrode BML. The buffer layer BFL may prevent an impurity from being diffused from the outside. The buffer layer BFL may include one of silicon oxide (SiOₓ), silicon nitride (SiNₓ), silicon oxynitride (SiOₓN_{y}), aluminum oxide (AlOₓ), and titanium oxide (TiOₓ).

The first transistor T1 may be electrically connected to light emitting elements LD1, LD2, and LD3. The first transistor T1 may include an active layer AT, a first transistor electrode TE1, a second transistor electrode TE2, and a gate electrode GE.

The active layer AT may be a semiconductor layer. The active layer AT may be disposed on the buffer layer BFL. The active layer AT may include one of poly-silicon, Low Temperature Polycrystalline Silicon (LTPS), amorphous silicon, and an oxide semiconductor.

The active layer AT may include a first contact region in contact with the first transistor electrode TE1 and a second contact region in contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate insulating layer GI may be disposed on the active layer AT and the buffer layer BFL. The gate electrode GE may be disposed on the gate insulating layer GI. A position of the gate electrode GE may correspond to that of the channel region of the active layer AT. For example, the gate electrode GE may be disposed on the channel region of the active layer AT with the gate insulating layer GI interposed therebetween.

The gate insulating layer GI may be disposed over the active layer AT. The gate insulating layer GI may include one of silicon oxide (SiOₓ), silicon nitride (SiNₓ), silicon oxynitride (SiOₓN_{y}), aluminum oxide (AlOₓ), and titanium oxide (TiOₓ).

The interlayer insulating layer ILD may be disposed over the gate electrode GE and the gate insulating layer GI. The interlayer insulating layer ILD may include one of silicon oxide (SiOₓ), silicon nitride (SiNₓ), silicon oxynitride (SiOₓN_{y}), aluminum oxide (AlOₓ), and titanium oxide (TiOₓ).

The first transistor electrode TE1 and the second transistor electrode TE2 may be disposed on the interlayer insulating layer ILD. The first transistor electrode TE1 may be in contact with the first contact region of the active layer AT while penetrating the gate insulating layer GI and the interlayer insulating layer ILD, and the second transistor electrode TE2 may be in contact with the second contact region of the active layer AT while penetrating the gate insulating layer GI and the interlayer insulating layer ILD. In an example, the first transistor electrode TE1 may be a drain electrode, and the second transistor electrode TE2 may be a source electrode. However, the present disclosure is not limited thereto.

In one or more embodiments, as shown in FIG. 10A, the second transistor electrode TE2 may be electrically connected to a first pixel electrode PE1 through an eighth contact hole CNT8 penetrating a first insulating layer INS1 and the protective layer PSV. For example, the eighth contact hole CNT8 may be formed while avoiding a first alignment electrode ALE1.

In one or more embodiments, a second power line PL2 may be disposed on the interlayer insulating layer ILD. As shown in FIG. 10A, the second power line PL2 may be electrically connected to a second pixel electrode PE2 through a ninth contact hole CNT9 penetrating the first insulating layer INS1 and the protective layer PSV. For example, the ninth contact hole CNT9 may be formed while avoiding a fourth alignment electrode ALE4.

In one or more embodiments, as shown in FIG. 10B, the first pixel electrode PE1 may be connected to the first alignment electrode ALE1 disposed on the protective layer PSV through a contact hole (e.g., a predetermined contact hole), and the first alignment electrode ALE1 may be connected to the second transistor electrode TE2 through a contact hole penetrating the protective layer PSV. The second pixel electrode PE2 may be connected to the second power line PL2 through the ninth contract hole CNT9 formed while avoiding the fourth alignment electrode ALE4. The fourth alignment electrode ALE4 may be a dummy electrode in the floating state.

In one or more embodiments, as shown in FIG. 10C, the second pixel electrode PE2 may be connected to the fourth alignment electrode ALE4 disposed on the protective layer PSV through a contact hole (e.g., a predetermined contact hole), and the fourth alignment electrode ALE4 may be connected to the second power line PL2 through a contact hole penetrating the protective layer PSV. The first pixel electrode PE1 may be connected to the second transistor electrode TE2 through the eighth contact hole CNT8 formed while avoiding the first alignment electrode ALE1. The fourth alignment electrode ALE4 may be a dummy electrode in the floating state.

The protective layer PSV may be disposed over the first transistor electrode TE1, the second transistor electrode TE2, the second power line PL2, and the interlayer insulating layer ILD. The protective layer PSV may include an organic material and/or an inorganic material.

The display element layer DPL may be disposed on the pixel circuit layer PCL. The display element layer DPL may include a first insulating pattern INP1, a second insulating pattern INP2, a third insulating pattern INP3, a fourth insulating pattern INP4, the first alignment electrode ALE1, a second alignment electrode ALE2, a third alignment electrode ALE3, a fourth alignment electrode ALE4, the first insulating layer INS1, a bank BNK, a first light emitting element LD1, a second light emitting element LD2, a third light emitting element LD3, the first pixel electrode PE1, a first connection electrode CNE1, a second connection electrode CNE2, the second pixel electrode PE2, and a color conversion layer CCL.

The first insulating pattern INP1, the second insulating pattern INP2, the third insulating pattern INP3, and the fourth insulating pattern INP4 may be disposed on the protective layer PSV. The first insulating pattern INP1, the second insulating pattern INP2, the third insulating pattern INP3, and the fourth insulating pattern INP4 may protrude in a thickness direction of the substrate SUB (e.g., a third direction DR3). The first insulating pattern INP1, the second insulating pattern INP2, the third insulating pattern INP3, and the fourth insulating pattern INP4 may include an organic material and/or an inorganic material.

The first light emitting element LD1 disposed between the first insulating pattern INP1 and the second insulating pattern INP2. The second light emitting element LD2 may be disposed between the second insulating pattern INP2 and the third insulating pattern INP3. The third light emitting element LD3 may be disposed between the third insulating pattern INP3 and the fourth insulating pattern INP4. For example, the first, second, third, and fourth insulating patterns INP1, INP2, INP3, and INP4 may be spaced from each other so that first light emitting elements LD1, second light emitting elements LD2, and third light emitting elements LD3 are accommodated and arranged therebetween.

The first alignment electrode ALE1, the second alignment electrode ALE2, the third alignment electrode ALE3, and the fourth alignment electrode ALE4 may be disposed on the protective layer PSV. A portion of the first alignment electrode ALE1 may be disposed over the first insulating pattern INP1, a portion of the second alignment electrode ALE2 may be disposed over the second insulating pattern INP2, a portion of the third alignment electrode ALE3 may be disposed over the third insulating pattern INP3, and a portion of the fourth alignment electrode ALE4 may be disposed over the fourth insulating pattern INP4. Each of the first alignment electrode ALE1, the second alignment electrode ALE2, the third alignment electrode ALE3, and the fourth alignment electrode ALE4 may serve as a reflective partition wall.

In one or more embodiments, the first alignment electrode ALE1 and the fourth alignment electrode ALE4 may be insulated from the light emitting elements LD1, LD2, and LD3 (described with reference to FIG. 10A).

In one or more r embodiments, the first alignment electrode ALE1 may be electrically connected to the first light emitting element LD1 through the first pixel electrode PE1, and the fourth alignment electrode ALE4 may be insulated from the light emitting elements LD1, LD2, and LD3 (described with reference to FIG. 10B).

In one or more embodiments, the fourth alignment electrode ALE4 may be electrically connected to the third light emitting element LD3 through the second pixel electrode PE2, and the first alignment electrode ALE1 may be insulated from the light emitting elements LD1, LD2, and LD3 (described with reference to FIG. 10C).

The second alignment electrode ALE2 and the third alignment electrode ALE3 may be insulated from the light emitting elements LD1, LD2, and LD3.

The first to fourth alignment electrodes ALE1 to ALE4 may include a conductive material. For example, the first to fourth alignment electrodes ALE1 to ALE4 may include one of silver (Al), magnesium (Mg), aluminum (Al), platinum (Pt), palladium (Pd), gold (Au), nickel (Ni), neodymium (Nd), iridium (Ir), chromium (Cr), titanium (Ti), and any alloy thereof. However, the present disclosure is not limited to the above-described example.

The first insulating layer INS1 may be disposed on the protective layer PSV. The first insulating layer INS1 may cover the first to fourth alignment electrodes ALE1 to ALE4. The first insulating layer INS1 may stabilize connection between electrode components, and reduce external influence. The first insulating layer INS1 may include one of silicon oxide (SiOₓ), silicon nitride (SiNₓ), silicon oxynitride (SiOₓN_{y}), aluminum oxide (AlOₓ), and titanium oxide (TiOₓ).

The bank BNK may be disposed on the first insulating layer INS1. The bank BNK may protrude in the thickness direction of the substrate SUB (e.g., the third direction DR3). The bank BNK may have a form surrounding the first emission area EMA1. In accordance with one or more embodiments of the present disclosure, the bank BNK may include an organic material and/or an inorganic material. The bank BNK may correspond to the non-emission area NEA.

The first, second, and third light emitting elements LD1, LD2, and LD3 may be disposed on the first insulating layer INS1. The first light emitting element LD1 may overlap with a portion of the first alignment electrode ALE1 and a portion of the second alignment electrode ALE2. The second light emitting element LD2 may overlap with a portion of the second alignment electrode ALE2 and a portion of the third alignment electrode ALE3. The third light emitting element LD3 may overlap with a portion of the third alignment electrode ALE3 and a portion of the fourth alignment electrode ALE4.

A second insulating layer INS2 may be disposed on each of the first, second, and third light emitting elements LD1, LD2, and LD3. The second insulating layer INS2 may cover an active layer (12 shown in FIG. 1) of each of the first, second, and third light emitting elements LD1, LD2, and LD3. Also, the second insulating layer INS2 may prevent a short circuit between adjacent electrodes (e.g., the first pixel electrode PE1 and the first connection electrode CNE1). The second insulating layer INS2 may include an organic material or an inorganic material.

The first pixel electrode PE1 may in contact with a first end portion of the first light emitting element LD1, and may be disposed on the first insulating layer INS1 and the second insulating layer INS2. The first pixel electrode PE1 may be an anode electrode electrically connected to the first transistor T1.

The second connection electrode CNE2 may be in contact with a second end portion of the second light emitting element LD2 and a first end portion of the third light emitting element LD3, and may be disposed on the first insulating layer INS1 and the second insulating layer INS2. For example, the second light emitting element LD2 and the third light emitting element LD3 may be connected in series by the second connection electrode CNE2.

In one or more embodiments, the first pixel electrode PE1 and the second connection electrode CNE2 may be formed with the same material at the same layer through the same process.

A third insulating layer INS3 may be disposed over the first pixel electrode PE1 and the second connection electrode CNE2, and may be disposed between the first pixel electrode PE1 and the first connection electrode CNE1, between the first connection electrode CNE1 and the second connection electrode CNE2, and between the second connection electrode CNE2 and the second pixel electrode PE2. The third insulating layer INS3 may prevent an electrical short circuit between the first pixel electrode PE1 and the first connection electrode CNE1, an electrical short circuit between the first connection electrode CNE1 and the second connection electrode CNE2, and an electrical short circuit between the second connection electrode CNE2 and the second pixel electrode PE2.

The third insulating layer INS3 may include one of silicon oxide (SiOₓ), silicon nitride (SiNₓ), silicon oxynitride (SiOₓN_{y}), aluminum oxide (AlOₓ), and titanium oxide (TiOₓ).

The first connection electrode CNE1 may be disposed on the first to third insulating layers INS1 to INS3, and may be in contact with a second end portion of the first light emitting element LD1 and a first end portion of the second light emitting element LD2. For example, the first light emitting element LD1 and the second light emitting element LD2 may be connected in series by the first connection electrode CNE1.

The second pixel electrode PE2 may be disposed on the first to third insulating layers INS1 to INS3, and may be in contact with a second end portion of the third light emitting element LD3. The second pixel electrode PE2 may be a cathode electrode electrically connected to the second power line PL2.

In one or more embodiments, the first connection electrode CNE1 and the second pixel electrode PE2 may be formed with the same material at the same layer through the same process.

The first pixel electrode PE1, the second pixel electrode PE2, the first connection electrode CNE1, and the second connection electrode CNE2 may include a conductive material. For example, the first pixel electrode PE1, the second pixel electrode PE2, the first connection electrode CNE1, and the second connection electrode CNE2 may include a transparent conductive material including one of Indium Tin Oxide (ITO), Indium Zinc Oxide (IZO), and Indium Tin Zinc Oxide (ITZO).

A fourth insulating layer INS4 may be disposed over the third insulating layer INS3, and cover the first connection electrode CNE1 and the second pixel electrode PE2. The fourth insulating layer INS4 may protect lower components of the display element layer DPL.

The fourth insulating layer INS4 may include one of silicon oxide (SiOₓ), silicon nitride (SiNₓ), silicon oxynitride (SiOₓN_{y}), aluminum oxide (AlOₓ), and titanium oxide (TiOₓ).

The color conversion layer CCL may be disposed on the fourth insulating layer INS4. The color conversion layer CCL may change a wavelength of light provided from the light emitting elements LD1, LD2, and LD3 or allow light provided from the light emitting elements LD1, LD2, and LD3 to be transmitted therethrough. In one or more embodiments, the light emitting elements LD1, LD2, and LD3 may emit blue light.

For example, when the first pixel PXL1 is a red pixel, a wavelength conversion pattern WCP of the color conversion layer CCL may include first color conversion particles (e.g., a quantum dot) for converting blue light into red light. The first color conversion particle may absorb blue light and emit red light by shifting a wavelength of the blue light according to energy transition.

When the first pixel PXL1 is a green pixel, the wavelength conversion pattern WCP of the color conversion layer CCL may include second color conversion particles (e.g., a quantum dot) for converting blue light into green light. The second color conversion particle may absorb blue light and emit green light by shifting a wavelength of the blue light according to energy transition.

The color conversion particles may have shape such as a spherical shape, a pyramid shape, a multi-arm shape, a cubic nano particle, a nano wire, a nano fabric, or a nano plate particle. However, the present disclosure is not limited thereto.

When the first pixel PXL1 is a blue pixel, the color conversion layer CCL may include a light transmission pattern instead of the wavelength conversion pattern WCP. The light transmission pattern is used to efficiently use light emitted from the light emitting element LD, and may include a plurality of light scattering particles dispersed in a matrix material (e.g., a predetermined matrix material) such as base resin. For example, the light transmission pattern may include light scattering particles such as silica, but the material constituting the light scattering particles is not limited thereto.

The optical layer OPL may be disposed on the display element layer DPL. In accordance with one or more embodiments, the optical layer OPL may include a first capping layer CAP1, a low refractive layer LRL, and a second capping layer CAP2.

The first capping layer CAP1 may seal (or cover) the color conversion layer CCL. The first capping layer CAP1 may be disposed between the low refractive layer LRL and the display element layer DPL. The first capping layer CAP1 may prevent infiltration of an impurity such as moisture or air from the outside.

For example, the first capping layer CAP1 may include one of silicon nitride (SiNₓ), silicon oxide (SiOₓ), silicon oxynitride (SiOₓN_{y}), and aluminum oxide (AlOₓ).

The low refractive layer LRL may be disposed between the first capping layer CAP1 and the second capping layer CAP2. The low refractive layer LRL may recycle light provided from the color conversion layer CCL, thereby improving light efficiency. To this end, the low refractive layer LRL may have a refractive index lower than a refractive index of the color conversion layer CCL.

In accordance with one or more embodiments, the low refractive layer LRL may include a base resin and hollow particles dispersed in the base resin. The hollow particle may include a hollow silica particle. Alternatively, the hollow particle may be a pore formed by porogen, but the present disclosure is not necessarily limited thereto. Also, the low refractive layer LRL may include one of a zinc oxide (ZnOₓ) particle, a titanium dioxide (TiOₓ) particle, and a nano silicate particle, but the present disclosure is not necessarily limited thereto.

The second capping layer CAP2 may be disposed on the low refractive layer LRL. The second capping layer CAP2 may prevent infiltration of an impurity such as moisture or air from the outside. The second capping layer CAP2 may include one of silicon nitride (SiNₓ), silicon oxide (SiOₓ), silicon oxynitride (SiOₓN_{y}), and aluminum oxide (AlOₓ).

The color filter layer CFL may be disposed on the second capping layer CAP2. The color filter layer CFL may include color filters CF1, CF2, and CF3, and an overcoat layer OC.

A first color filter CF1 may be disposed throughout the first emission area EMA1 and the non-emission area NEA, corresponding to a color of the first pixel PXL1. The first color filter CF1 allows light of the color of the first pixel PXL1 to be transmitted therethrough, and allows light of colors of the second and third pixels PXL2 and PXL3 not to be transmitted therethrough.

The first color filter CF1, a second color filter CF2, and a third color filter CF3 may be sequentially stacked in the non-emission area NEA.

The overcoat layer OC may be disposed over the color filters CF1, CF2, and CF3. The overcoat layer OC may prevent moisture or air from infiltrating into a lower member. Also, the overcoat layer OC may protect the above-described lower member from a foreign matter such as dust.

In accordance with one or more embodiments, the overcoat layer OC may include an organic material such as acryl resin, epoxy resin, phenolic resin, polyamide resin, polyimide resin, unsaturated polyester resin, poly-phenylene ether resin, poly-phenylene sulfide resin, or benzocyclobutene (BCB). However, the present disclosure is not necessarily limited to the above-described example.

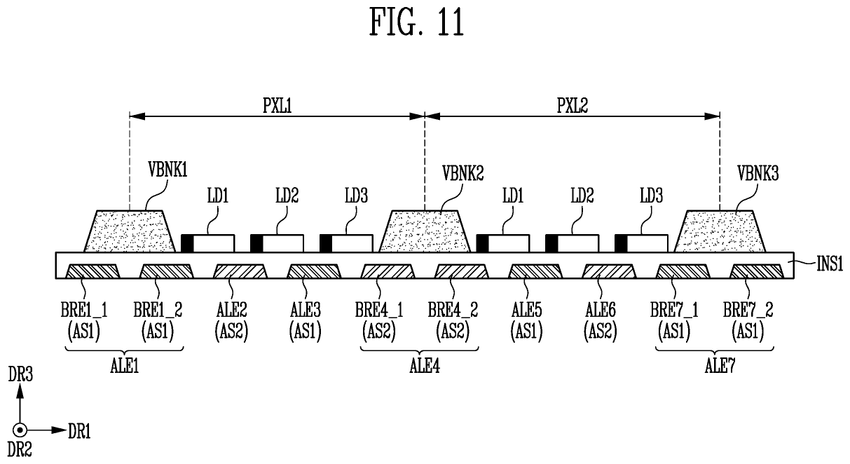

FIG. 11 is a conceptual view illustrating an example of the alignment electrodes included in the pixels shown in FIG. 7.

Referring to FIGS. 7 and 11, the first to seventh alignment electrodes ALE1 to ALE7 may be arranged along the first direction DR1.

In the alignment process of the light emitting elements LD1, LD2, and LD3, a first alignment signal AS1 may be supplied to the first, third, fifth, and seventh alignment electrodes ALE1, ALE3, ALE5, and ALE7, and a second alignment signal AS2 may be supplied to the second, fourth, and sixth alignment electrodes ALE2, ALE4, and ALE6. For example, one of the first alignment signal AS1 and the second alignment signal AS2 may be an AC signal, and the other of the first alignment signal AS1 and the second alignment signal AS2 may be a ground signal. In other words, different alignment signals may be supplied to adjacent alignment electrodes. Therefore, the first, second, and third light emitting elements LD1, LD2, and LD3 may be aligned by a force according to an electric field formed between adjacent alignment electrodes.

The first alignment electrode ALE1 for receiving the first alignment signal AS1 may be disposed on the bottom of the first vertical extension part VBNK1 of the bank BNK. The fourth alignment electrode ALE4 for receiving the second alignment signal AS2 may be disposed on the bottom of the second vertical extension part VBNK2 of the bank BNK. The seventh alignment electrode ALE7 for receiving the first alignment signal AS1 may be disposed on the bottom of the third vertical extension part VBNK3 of the bank BNK.

In one or more embodiments, different alignment signals may be supplied to alignment electrodes overlapping with the bottom of vertical extension parts adjacent to each other. This is for the purpose of aligning light emitting elements of a light emitting unit configured with three serial stages.

In one or more embodiments, each of the first, fourth, and seventh alignment electrodes ALE1, ALE4, and ALE7 may include a first branch electrode BRE1_1, BRE4_1 or BRE7_1 and a second branch electrode BRE1_2, BRE4_2 or BRE7_2.

As shown in FIG. 11, the third light emitting elements LD3 of the first pixel PXL1 may be arranged by an electric field formed between a first branch electrode BRE4_1 of the fourth alignment electrode ALE4 and the third alignment electrode ALE3. In addition, the first light emitting elements LD1 of the second pixel PXL2 may be arranged by an electric field formed by a second branch electrode BRE4_2 of the fourth alignment electrode ALE4 and the fifth alignment electrode ALE5.

Because the same signal is supplied to branch electrodes BRE1_1 and BRE1_2 of the first alignment electrode ALE1, any electric field is not formed on the bottom of the first vertical extension part VBNK1, or a force according to an electric field may be insignificant. Therefore, light emitting elements are not disposed on the first vertical extension part VBNK1 while being separated from positions thereof. Similarly, because the same signal is supplied to branch electrodes BRE4_1 and BRE4_2 of the fourth alignment electrode ALE4, any electric field is not formed on the bottom of the second vertical extension part VBNK2, and light emitting elements are not moved onto the second vertical extension part VBNK2. For such a reason, any electric field is not formed on the bottom of the third vertical extension part VBNK3, and light emitting elements are not moved onto the third vertical extension part VBNK3.

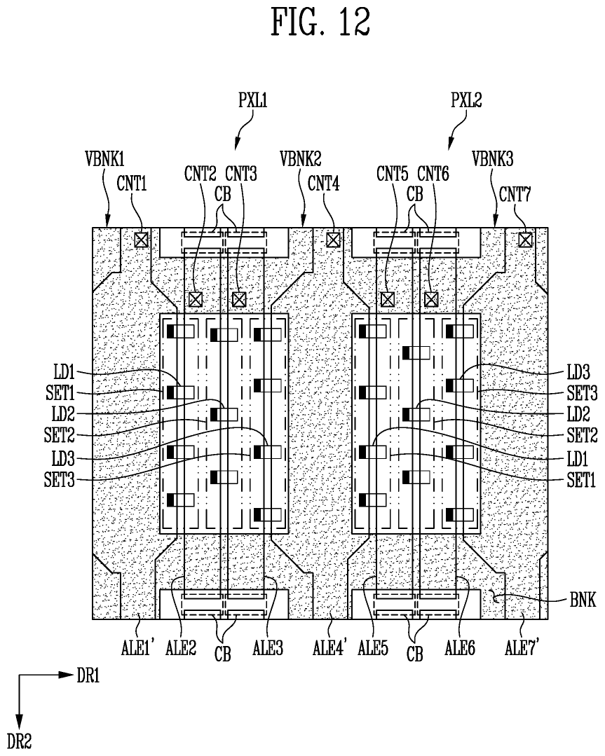

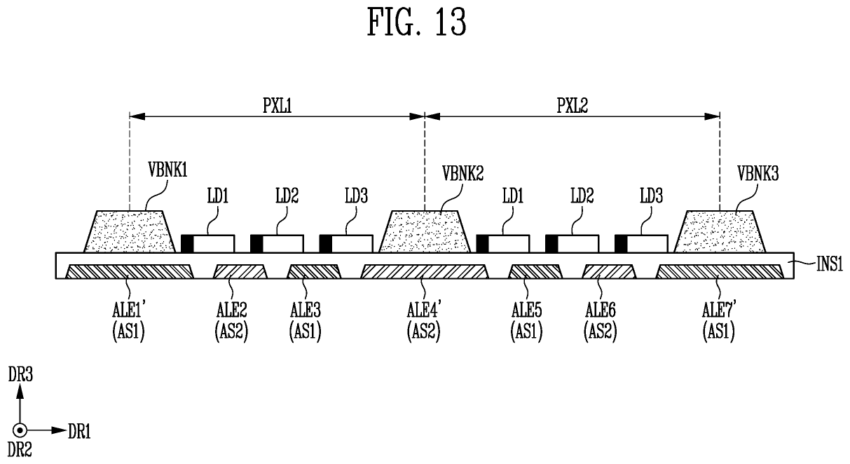

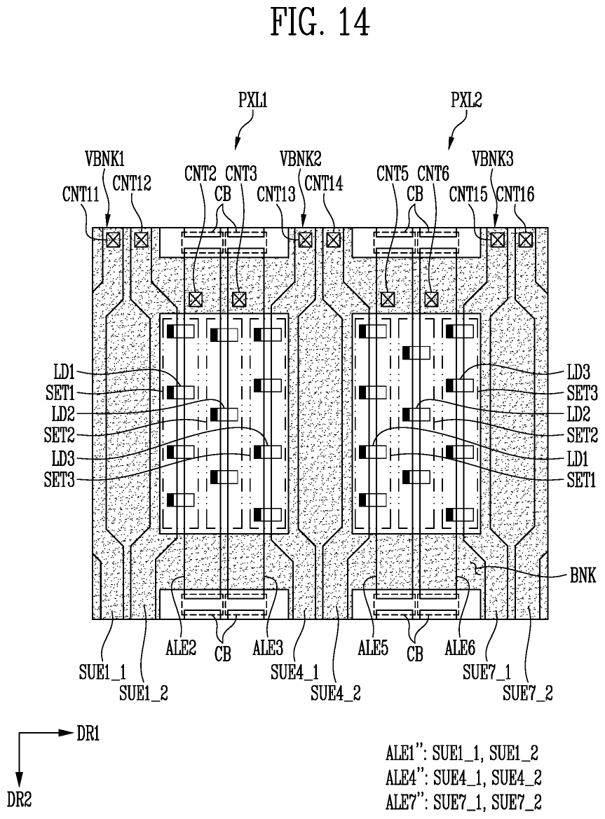

FIG. 12 is a schematic plan view illustrating an example of the pixels included in the display device shown in FIG. 3. FIG. 13 is a conceptual view illustrating an example of alignment electrodes included in the pixels shown in FIG. 12.

In FIGS. 12 and 13, components identical to those described with reference to FIGS. 7 and 11 are designated by like reference numerals, and their overlapping descriptions will be omitted.

Referring to FIGS. 12 and 13, each of first, fourth, and seventh alignment electrodes ALE1′, ALE4′, and ALE7′ does not branch off in an area in which each of the first, fourth, and seventh alignment electrodes ALE1′, ALE4′, and ALE7′ overlaps with the bank BNK.

In one or more embodiments, as shown in FIG. 13, a width of each of the first, fourth, and seventh alignment electrodes ALE1′, ALE4′, and ALE7′ in the first direction DR1 may be greater than a width of each of the other alignment electrodes ALE2, ALE3, ALE5, and ALE6 in the first direction DR1. For example, the first alignment electrode ALE1′ on the bottom of the first vertical extension part VBNK1 may have a pipe shape. Thus, an electric field on the bottom of the first vertical extension part VBNK1 can be more effectively removed.

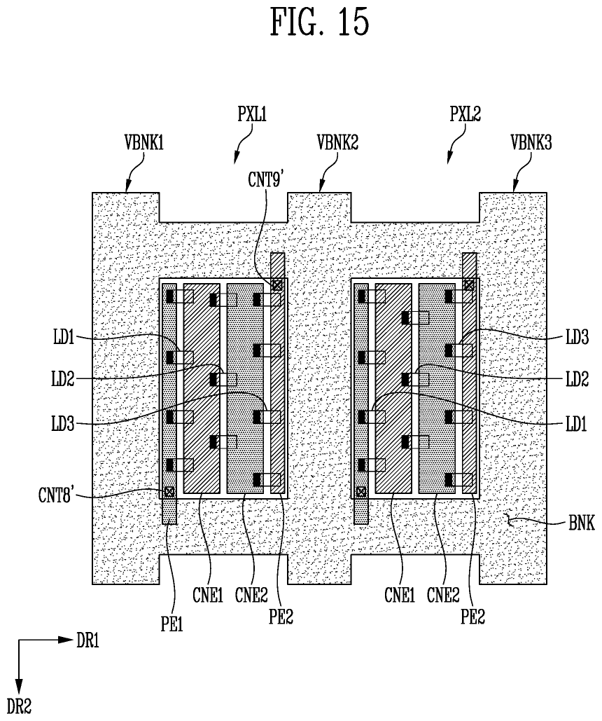

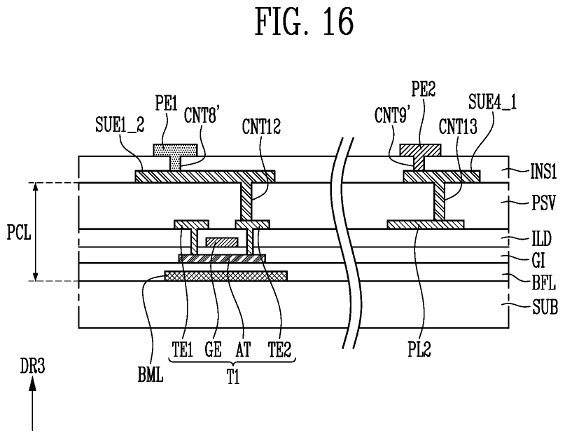

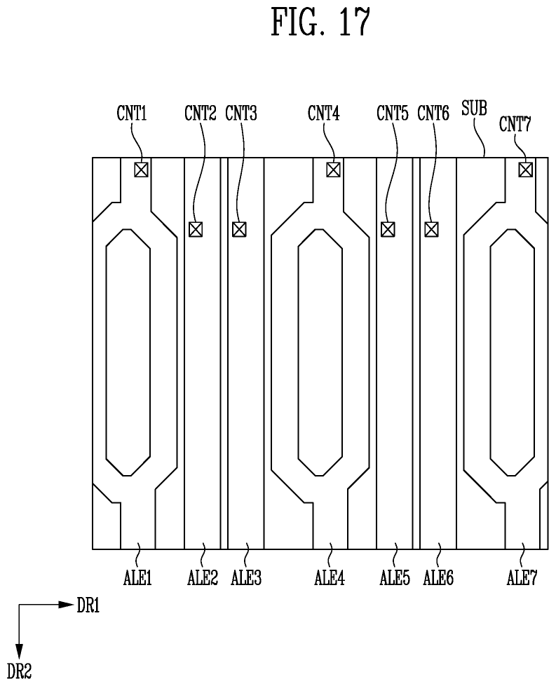

FIGS. 14 and 15 are schematic plan views illustrating an example of the pixels included in the display device shown in FIG. 3. FIG. 16 is a schematic sectional view illustrating an example of a partial area shown in FIG. 15.

In FIGS. 14, 15, and 16, components identical to those described with reference to FIGS. 7, 8, and 10A are designated by like reference numerals, and their overlapping descriptions will be omitted.

Referring to FIGS. 14, 15, and 16, each of first, fourth, and seventh alignment electrodes ALE1″, ALE4″, and ALE7″ may include a first sub-electrode SUE1_1, SUE4_1 or SUE7_1 and a second sub-electrode SUE1_2, SUE4_2 or SUE7_2.

The first sub-electrode SUE1_1, SUE4_1 or SUE7_1 and the second sub-electrode SUE1_2, SUE4_2 or SUE7_2 may be spaced from each other. For example, a first sub-electrode SUE4_1 of the fourth alignment electrode ALE4″ may overlap with the third light emitting elements LD3 of the first pixel PXL1 and the second vertical extension part VBNK2, and a second sub-electrode SUE4_2 of the fourth alignment electrode ALE4″ may overlap with the first light emitting elements LD1 of the second pixel PXL2 and the second vertical extension part VBNK2. The first sub-electrode SUE4_1 of the fourth alignment electrode ALE4″ and the second sub-electrode SUE4_2 of the fourth alignment electrode ALE4″ may be spaced from each other.

In the alignment process, the same alignment signal may be supplied to a first sub-electrode SUE1_1 and a second sub-electrode SUE1_2 of the first alignment electrode ALE1″. Subsequently, in the display device, the first sub-electrode SUE1_1 may be connected to the second power line PL2 through an eleventh contact hole CNT11, and the second sub-electrode SUE1_2 may be connected to the second transistor electrode TE2 of the first pixel PXL1 through a twelfth contact hole CNT12. That is, after alignment is completed, the first sub-electrode SUE1_1 and the second sub-electrode SUE1_2 may serve as bridge electrodes that transfer different signals.

Similarly, in the alignment process, the same alignment signal may be supplied to the first sub-electrode SUE4_1 and the second sub-electrode SUE4_2 of the fourth alignment electrode ALE4″. Subsequently, in the display device, the first sub-electrode SUE4_1 may be connected to the second power line PL2 through a thirteenth contact hole CNT13, and the second sub-electrode SUE4_2 may be connected to the second transistor electrode TE2 of the second pixel PXL2 through a fourteenth contact hole CNT14. That is, after alignment is completed, the first sub-electrode SUE4_1 and the second sub-electrode SUE4_2 may serve as bridge electrodes that transfer different signals.

In the alignment process, the same alignment signal may be supplied to a first sub-electrode SUE7_1 and a second sub-electrode SUE7_2 of the seventh alignment electrode ALE7″. Subsequently, in the display device, the first sub-electrode SUE7_1 may be connected to the second power line PL2 through a fifteenth contact hole CNT15, and the second sub-electrode SUE7_2 may be connected to a second transistor electrode TE2 of another pixel through a sixteenth contact hole CNT16.

As shown in FIGS. 15 and 16, the first pixel electrode PE1 of the first pixel PXL1 may be electrically connected to the second sub-electrode SUE1_2 of the first alignment electrode ALE1″ through an eighth contact hole CNT8′. The second pixel electrode PE2 of the first pixel PXL1 may be electrically connected to the first sub-electrode SUE4_1 of the fourth alignment electrode ALE4″ through a ninth contact hole CNT9′.

Thus, the sub-electrodes serve as bridge electrodes for connection between the pixel electrodes PE1 and PE2 and lower components, so that power loss in signal transfer can be reduced.

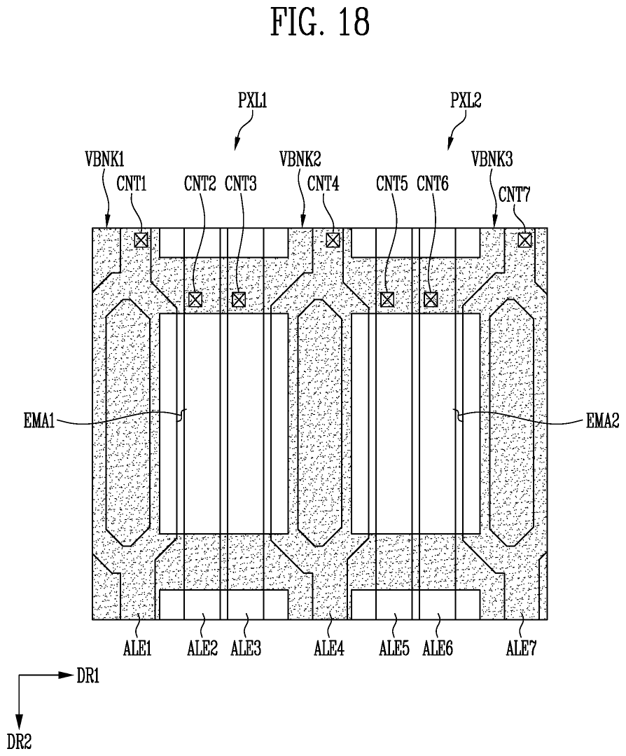

FIGS. 17 to 20 are schematic plan views illustrating a method of manufacturing the display device in accordance with one or more embodiments of the present disclosure.

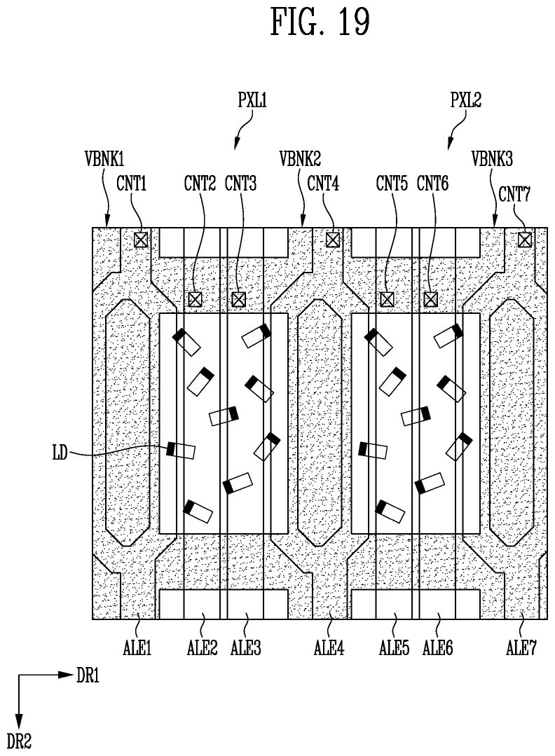

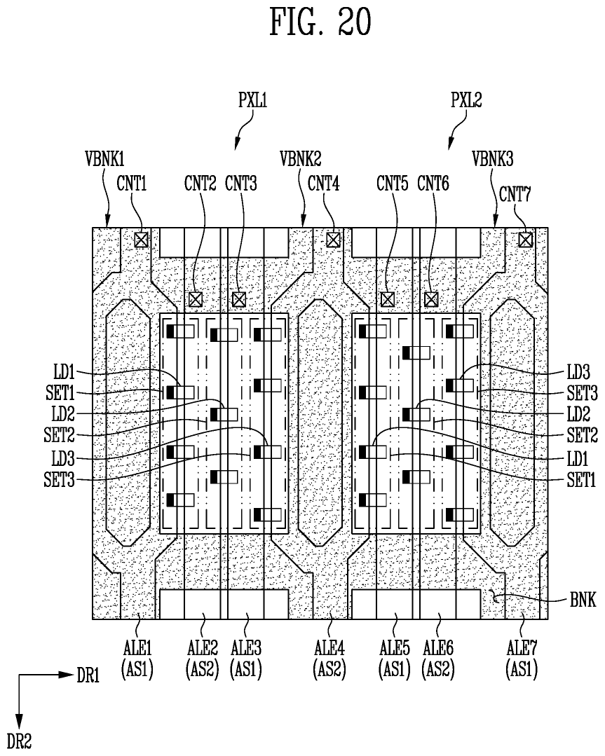

Referring to FIGS. 17 to 20, the method of manufacturing the display device forming, on a substrate SUB, first to seventh alignment electrodes ALE1 to ALE7 arranged while being spaced from each other in the first direction DR1 (see FIG. 17), forming a bank BNK defining a first emission area EMA1 and a second emission area EMA2 on the first to seventh alignment electrodes ALE1 to ALE7 (see FIG. 18), providing light emitting elements LD in the first emission area EMA1 and the second emission area EMA2 (see FIG. 19), and arranging the light emitting elements LD by using an alignment signal (see FIG. 20).

As shown in FIG. 17, first to seventh alignment electrodes ALE1 to ALE7 may be formed on a substrate SUB. For example, the first to seventh alignment electrodes ALE1 to ALE7 may be formed through patterning of a conductive material by using a mask. Each of the first to seventh alignment electrodes ALE1 to ALE7 may be connected to a signal line to which a corresponding alignment signal is transferred through a corresponding contact hole from among contact holes CNT1 to CNT7.

As shown in FIG. 18, a bank BNK may be formed, which defines a first emission area EMA1 of a first pixel PXL1 and a second emission area EMA2 of a second pixel PXL2. The bank BNK may be formed through patterning using a mask with respect to an organic material including a light blocking material.

In one or more embodiments, the first alignment electrode ALE1 may overlap with the first vertical extension part VBNK1 of the bank BNK and the first emission area EMA1, the fourth alignment electrode ALE4 may overlap with the first emission area EMA1, the second emission area EMA2, and the second vertical extension part VBNK2 of the bank BNK, and the seventh alignment electrode ALE7 may overlap with the third vertical extension part VBNK3 of the bank BNK.

As shown in FIG. 19, light emitting elements LD may be provided in the first emission area EMA1 and the second emission area EMA2. In one or more embodiments, ink as a volatile solvent, which includes the light emitting elements LD, may be input to the first emission area EMA1 and the second emission area EMA2, which are spaces defined by the bank BNK. The light emitting elements LD may be input through an inkjet printing process, a slit coating process, or other various processes.

As shown in FIG. 20, a first alignment signal AS1 may be applied to the first alignment electrode ALE1, the third alignment electrode ALE3, a fifth alignment electrode ALE5, and a seventh alignment electrode ALE7, and a second alignment signal AS2 may be applied to the second alignment electrode ALE2, the fourth alignment electrode ALE4, and a sixth alignment electrode ALE6. Accordingly, the light emitting elements LD may be arranged as first light emitting elements LD1 of a first serial stage SET1, second light emitting elements LD2 of a second serial stage SET2, and third light emitting elements LD3 of a third serial stage SET3.

Any electric field may not be formed at a portion overlapping with first to third vertical extension parts VBNK1, VBNK2, and VBNK3. Therefore, the light emitting elements LD may not be disposed on the first to third vertical extension parts VBNK1, VBNK2, and VBNK3.

After the first, second, and third light emitting elements LD1, LD2, and LD3 are aligned, the solvent may be volatilized or be removed though another process.

Subsequently, in one or more embodiments, both ends of each of the second alignment electrode ALE2, the third alignment electrode ALE3, the fifth alignment electrode ALE5, and the sixth alignment electrode ALE6 may be cut. Therefore, as shown in FIG. 7, each of the second alignment electrode ALE2, the third alignment electrode ALE3, the fifth alignment electrode ALE5, and the sixth alignment electrode ALE6 may include cut end portions CB. For example, the second alignment electrode ALE2, the third alignment electrode ALE3, the fifth alignment electrode ALE5, and the sixth alignment electrode ALE6 may have the floating state as dummy electrodes.

As described above, in the display device and the method of manufacturing the same in accordance with the embodiments of the present disclosure, alignment electrodes (e.g., the first, fourth, and seventh alignment electrodes ALE1, ALE4, and ALE7) are disposed such that only one of the first alignment signal and the second alignment signal is transferred to each of alignment electrodes overlapping with each of the vertical extension parts of the bank BNK. Thus, an electric field formed on the bottom of the bank may be removed in the alignment process of the light emitting elements. Accordingly, in arrangement of the light emitting elements forming the first to third serial stages, an arrangement defect in which light emitting elements are disposed on the bank BNK (e.g., the vertical extension parts VBNK) while being separated from positions thereof can be reduced or minimized.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
First, second, third, and fourth alignment electrodes sequentially arranged while being spaced from each other along a first direction in a first emission area;
a bank on the first, second, third, and fourth alignment electrodes, the bank comprising first and second horizontal extension parts extending in the first direction and first, second, and third vertical extension parts extending in a second direction crossing the first direction, the bank partitioning the first emission area and a second emission area;
first light emitting elements overlapping with the first alignment electrode and the second alignment electrode;
second light emitting elements overlapping with the second alignment electrode and the third alignment electrode; and
third light emitting elements overlapping with the third alignment electrode and the fourth alignment electrode,
wherein the first alignment electrode overlaps with the first vertical extension part and the first emission area, and
wherein the fourth alignment electrode overlaps with the first emission area, the second emission area, and the second vertical extension part.

2. The display device of claim 1, wherein, when the first, second, and third light emitting elements are aligned, the first alignment electrode and the third alignment electrode are configured to receive a first alignment signal, and the second alignment electrode and the fourth alignment electrode are configured to receive a second alignment signal.

3. The display device of claim 2, wherein the first alignment signal is different from the second alignment signal, and
wherein a planar shape of the first alignment electrode is identical to a planar shape of the fourth alignment electrode.

4. The display device of claim 3, wherein each of the first alignment electrode and the fourth alignment electrode comprises a first branch electrode and a second branch electrode extending in the second direction and overlapping with the bank.

5. The display device of claim 4, wherein the first branch electrode and the second branch electrode respectively overlap with emission areas adjacent to each other.

6. The display device of claim 2, further comprising a first pixel electrode, a first connection electrode, a second connection electrode, and a second pixel electrode, in each of the first emission area and the second emission area, that are spaced from each other along the first direction.

7. The display device of claim 6, wherein the first light emitting elements are connected in parallel between the first pixel electrode and the first connection electrode,
wherein the second light emitting elements are connected in parallel between the first connection electrode and the second connection electrode, and
wherein the third light emitting elements are connected in parallel between the second connection electrode and the second pixel electrode.

8. The display device of claim 7, wherein the first light emitting elements, the second light emitting elements, and the third light emitting elements are connected in series.

9. The display device of claim 7, wherein the first pixel electrode overlaps with a portion of the first alignment electrode,
wherein the first connection electrode overlaps with a portion of the second alignment electrode,
wherein the second connection electrode overlaps with a portion of the third alignment electrode, and
wherein the second pixel electrode overlaps with a portion of the fourth alignment electrode.

10. The display device of claim 9, wherein the first pixel electrode is electrically connected to a transistor thereunder through a first contact hole at a portion not overlapping with the first alignment electrode.

11. The display device of claim 9, wherein the second pixel electrode is electrically connected to a power line thereunder through a second contact hole at a portion not overlapping with the fourth alignment electrode.

12. The display device of claim 9, wherein the first pixel electrode is insulated from the first alignment electrode, and
wherein the second pixel electrode is insulated from the fourth alignment electrode.

13. The display device of claim 2, further comprising fifth, sixth, and seventh alignment electrodes sequentially arranged while being spaced from each other along the first direction in the second emission area,
wherein the seventh alignment electrode overlaps with the second emission area and the third vertical extension part.

14. The display device of claim 13, wherein, when the first, second, and third light emitting elements are aligned, the sixth alignment electrode is configured to receive the second alignment signal, and the fifth alignment electrode and the seventh alignment electrode are configured to receive the first alignment signal.

15. The display device of claim 2, wherein the fourth alignment electrode comprises:
a first sub-electrode overlapping with the third light emitting elements and the second vertical extension part; and
a second sub-electrode spaced from the first sub-electrode, the second sub-electrode overlapping with the second vertical extension part and the second emission area.

16. The display device of claim 15, wherein the first pixel electrode is electrically connected to the first alignment electrode through a first contact hole, and
wherein the second pixel electrode is electrically connected to the first sub-electrode through a second contact hole.

17. A method of manufacturing a display device, the method comprising:
forming, on a substrate, first, second, third, and fourth alignment electrodes arranged while being spaced from each other along a first direction;
forming a bank defining a first emission area and a second emission area on the first, second, third, and fourth alignment electrodes;
providing light emitting elements in the first emission area and the second emission area; and
arranging the light emitting elements by applying a first alignment signal to the first alignment electrode and the third alignment electrode and applying a second alignment signal to the second alignment electrode and the fourth alignment electrode,
wherein the bank comprises first and second horizontal extension parts extending in the first direction and first, second, and third vertical extension parts extending in a second direction crossing the first direction, and
wherein the first alignment electrode overlaps with the first vertical extension part and the first emission area, and
the fourth alignment electrode overlaps with the first emission area, the second emission area, and the second vertical extension part.

18. The method of claim 17, wherein the first alignment signal is different from the second alignment signal, and
wherein a planar shape of the first alignment electrode is identical to a planar shape of the fourth alignment electrode.

19. The method of claim 18, wherein the light emitting elements are arranged in three columns in each of the first emission area and the second emission area.

20. The method of claim 18, further comprising cutting both ends of each of the second alignment electrode and the third alignment electrode.
